(19) United States
(12) Patent Application Publication
(10) Pub. No.: US 2023/0302922 A1
(43) Pub. Date: Sep. 28, 2023

(54) SUSTAINING STATE OF CHARGE AND STATE OF HEALTH IN FUEL CELL MODULES AND BATTERIES OF A FUEL CELL HYBRID SYSTEM

(71) Applicants: CUMMINS INC., Columbus, IN (US); HYDROGENICS CORPORATION, Mississauga (CA)

(72) Inventors: Agneya TURLAPATI, Indianapolis, IN (US); Akshat Abhay RAUT, Columbus, IN (US); Arka Saha RAY, Pune (IN); Anant PURI, Greenwood, IN (US); David P. GENTER, Columbus, IN (US); Aaron William BEINBORN, Greenwood, IN (US); Joseph P. CHANDRARAJ, Austin, TX (US); Sumit TRIPATHI, Columbus, IN (US); Heonjoong LEE, Columbus, IN (US)

(21) Appl. No.: 18/189,851

(22) Filed: Mar. 24, 2023

Related U.S. Application Data
(60) Provisional application No. 63/324,430, filed on Mar. 28, 2022.

(51) Int. Cl. B60L 50/75; G01R 31/382; G01R 31/392; H01M 8/04858; H01M 8/04537

(52) U.S. Cl. CPC B60L 50/75; G01R 31/382; G01R 31/392; H01M 8/0491; H01M 8/04656; H01M 2250/20

(57) ABSTRACT

A system for a fuel cell vehicle including a plurality of fuel cell modules, a plurality of battery packs, and a controller. At least one of the plurality of fuel cell modules having a state of health (SOH) different from a corresponding SOH of other fuel cell modules. Each battery pack including a plurality of battery cells. At least one of the plurality of battery packs having a SOH different from a corresponding SOH of other battery packs. The controller is communicatively coupled to monitor and control operation of the plurality of fuel cell modules and the plurality of battery packs. The controller is configured to receive a power demand and determine a power split between the plurality of fuel cell modules and the plurality of battery packs based on an operating phase of the vehicle.

### CROSS-REFERENCE TO RELATED APPLICATIONS

This non-provisional application claims the benefit and priority, under 35 U.S.C. § 119(e) and any other applicable laws or statutes, to U.S. Provisional Patent Application Ser. No. 63/324,430 filed Mar. 28, 2022, the entire disclosure of which is hereby expressly incorporated herein by reference.

### TECHNICAL FIELD

The present disclosure generally relates to achieving and maintaining a predefined state of charge (SOC) operation for a battery pack of a fuel cell system.

### BACKGROUND

Fuel cell systems are known for their efficient use of fuel to develop direct current (DC) electric power. A fuel cell produces electricity by electrochemically combining a fuel and an oxidant across an ionic conducting layer, the electrolyte, for which many fuel cells are named. Individual fuel cells may be interconnected in series or in parallel and assembled to form a fuel cell stack configured to produce electrical power to support a specific application.

### SUMMARY

Embodiments of the present invention are included to meet these and other needs.

In one aspect, described herein, a system for a fuel cell vehicle comprises a plurality of fuel cell modules, a plurality of battery packs, and a controller. At least one of the plurality of fuel cell modules has a state of health (SOH) different from a corresponding SOH of another fuel cell module in the plurality of fuel cell modules. Each battery pack includes a plurality of battery cells. At least one of the plurality of battery packs has a SOH different from a corresponding SOH of another battery pack in the plurality of battery packs. The controller is communicatively coupled to the plurality of fuel cell modules and the plurality of battery packs. The controller is configured to monitor and control operation of the plurality of fuel cell modules or the plurality of battery packs. The controller is configured to receive a power demand of the vehicle. The controller is configured to determine a power split between the plurality of fuel cell modules and the plurality of battery packs based on an operating phase of the vehicle. The controller is configured to cause a flow of power based on a determined power split from the plurality of fuel cell modules and from the plurality of battery packs to meet the power demand.

In some embodiments, the controller may be configured to determine the power split based on at least one of the SOH of the plurality of battery packs, the SOH of the plurality of fuel cell modules, and a state of charge (SOC) of the plurality of battery packs. In some embodiments, the plurality of battery cells may be combined to provide a plurality of battery modules, and wherein a SOH of at least one of the plurality of battery modules may be different from a SOH of at least one other of the plurality of battery modules.

In some embodiments, the controller may be configured to, in response to the power demand being greater than a threshold, determine an even power split between the plurality of fuel cell modules and the plurality of battery packs and may cause the flow of power from the plurality of fuel cells modules and the plurality of battery packs to power a traction motor to propel the vehicle. In some embodiments, the even power split may be determined further in response to detecting that the vehicle is moving up an incline.

In some embodiments, the controller may be configured to, in response to input parameters, determine a vehicle operational state, determine a battery power rate based on a relational or lookup model, and may cause at least one of the events of powering a traction motor to propel the vehicle, powering vehicle accessory systems, or causing the plurality of fuel cell modules to charge the plurality of battery packs. In some embodiments, the controller may be configured to cause the plurality of fuel cell modules to charge the plurality of battery packs further in response to detecting a truck bed of the vehicle is active. In some embodiments, the controller may be configured to determine a battery SOH correction factor to be used in determining the power split between the plurality of fuel cell modules and the plurality of battery packs.

According to a second aspect, described herein, a method for a fuel cell vehicle comprises receiving values of a plurality of input parameters, an actual state of health (SOH) of a battery, and a state of charge (SOC) of the battery, determining an operating state of the vehicle, determining a battery SOH correction factor, determining a power split between a plurality of fuel cell modules and the battery, and causing a flow of power from the plurality of fuel cell modules and to and from the battery based on the determined power split.

In some embodiments, the method may further comprise, in response to determining that the operating state of the vehicle is one of an idle state, a standby state, or a stationary state, determining a battery charge rate for charging the battery while the vehicle is in the idle state, the standby state, or the stationary state. In some embodiments, the method may further comprise, in response to determining that the operating state of the vehicle is a moving state, determining a battery charge rate for charging the battery while the vehicle is moving.

In some embodiments, the plurality of input parameters may include one of an actual battery SOC, a target battery SOC, a battery temperature, a battery voltage, a battery current, an ambient temperature, and an ambient pressure. In some embodiments, the power split may be determined based on a predictive fuel cell power demand estimation. In some embodiments, the predictive fuel cell power demand estimation may be provided by a cloud-based analytical system. In some embodiments, the cloud-based analytical system may determine the predictive fuel cell power demand estimation based on values of one of a speed of the vehicle, a weight of the vehicle, wheel power, a configuration of the vehicle, an ambient temperature, an upcoming route target speed, an upcoming route target grade, and an accessory power.

According to a third aspect, described herein, a system for a fuel cell vehicle comprises a plurality of fuel cell modules, a plurality of battery packs, and a controller. Each fuel cell module of the plurality of fuel cell modules includes a plurality of fuel cell stacks. Each battery pack of the plurality of battery packs includes a plurality of battery modules. At least one of the plurality of battery modules has a state of health (SOH) different from a corresponding SOH of another battery module in the plurality of battery modules. The controller is communicatively coupled to monitor and control operation of the plurality of fuel cell modules and the plurality of battery packs. The controller is configured to receive a power demand. The controller is configured to determine a power set point for each of the plurality of fuel cell stacks of each of the plurality of fuel cell modules. The controller is configured to cause a flow of power from each of the plurality of fuel cell stacks of each of the plurality of fuel cell modules based on the determined power set point of each of the plurality of fuel cell stacks.

In some embodiments, to determine the power set point may include to determine whether the determined power set point is less than an idle power threshold, and wherein the controller may be configured to, in response to the determined power set point being less than the idle power threshold, update a value of the idle power threshold to correspond to a value of the determined power set point. In some embodiments, the controller may be configured to, in response to the determined power set point being greater than the idle power threshold, determine whether a new fuel flow based on the determined power set point is less than a previous fuel flow based on the idle power threshold.

In some embodiments, the controller may be configured to, in response to the new fuel flow based on the determined power set point being less than the previous fuel flow based on the idle power threshold, update the value of the idle power threshold to correspond to the value of the determined power set point. In some embodiments, the controller may be configured to, in response to the new fuel flow based on the determined power set point being greater than the previous fuel flow based on the idle power threshold, incrementally adjust the determined power set point to correspond to an updated determined power set point.

### BRIEF DESCRIPTION OF THE DRAWINGS

The detailed description particularly refers to the following figures, in which:

FIG. 1A is a schematic view of an exemplary fuel cell system including an air delivery system, a hydrogen delivery system, and a fuel cell module including a stack of multiple fuel cells;

FIG. 1B is a cutaway view of an exemplary fuel cell system including an air delivery system, hydrogen delivery systems, and a plurality of fuel cell modules each including multiple fuel cell stacks;

FIG. 1C is a perspective view of an exemplary repeating unit of a fuel cell stack of the fuel cell system of FIG. 1A;

FIG. 1D is a cross-sectional view of an exemplary repeating unit of the fuel cell stack of FIG. 1C;

FIG. 2A is a block diagram illustrating an example implementation of a fuel cell vehicle;

FIG. 2B is a block diagram illustrating the example fuel cell vehicle for specialized off-highway/on-highway applications;

FIG. 3 is a block diagram illustrating an example control system for controlling the fuel cell vehicle of FIG. 2A;

FIG. 4 is a graph illustrating a change in speed of the fuel cell vehicle of FIG. 2A with respect to time during an example operating cycle M;

FIG. 5 is a graph illustrating a change in elevation of the fuel cell vehicle of FIG. 2A with respect to time during the example operating cycle M;

FIG. 6 is a graph illustrating a flow of power from the fuel cell stack and to and from a battery of the fuel cell vehicle of FIG. 2A;

FIG. 7 is a graph illustrating a change in a state of charge (SOC) of the battery of the fuel cell vehicle of FIG. 2A;

FIGS. 8, 9 and 10 are block diagrams illustrating control strategies applied in response to a change in power demand during the example operating cycle M;

FIG. 11 is a block diagram illustrating an example power control system in accordance with the present disclosure;

FIG. 12 is a block diagram illustrating an example implementation of the power control system of FIG. 11 configured to communicate with a cloud network;

FIGS. 13, 14, 15, and 16 are block diagrams illustrating an open loop control strategy, a closed loop control strategy, a hybrid control strategy, and another hybrid control strategy, respectively, for a fuel cell controller of the fuel cell vehicle of FIG. 2A;

FIG. 17 is a graph illustrating a change in fuel efficiency of a fuel cell module with respect to a change in fuel cell module power; and

FIG. 18 is a block diagram illustrating an example process flow for controlling power flow from the fuel cell stack and to and from the battery of the fuel cell vehicle of FIG. 2A.

### DETAILED DESCRIPTION

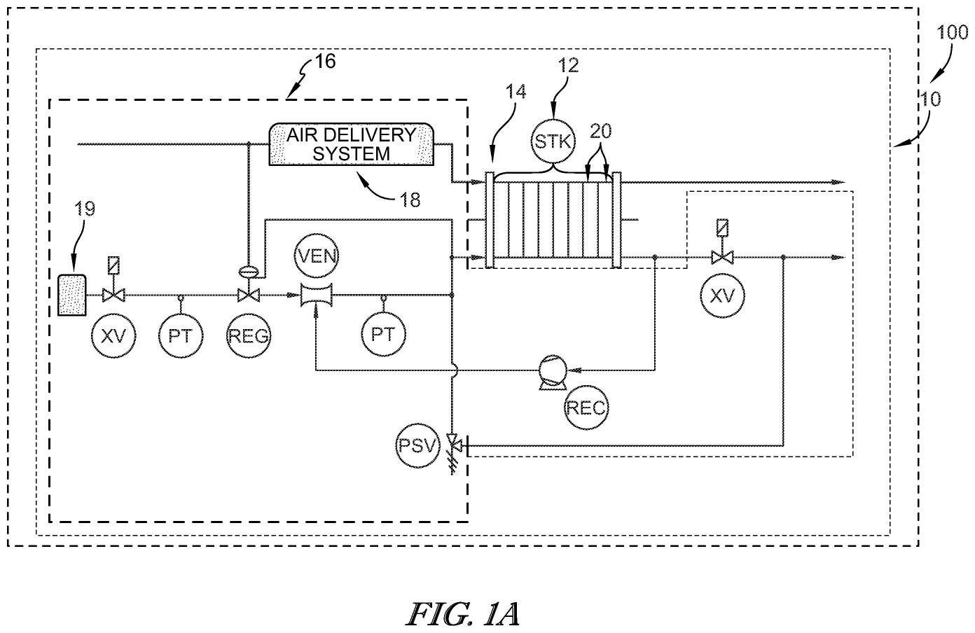

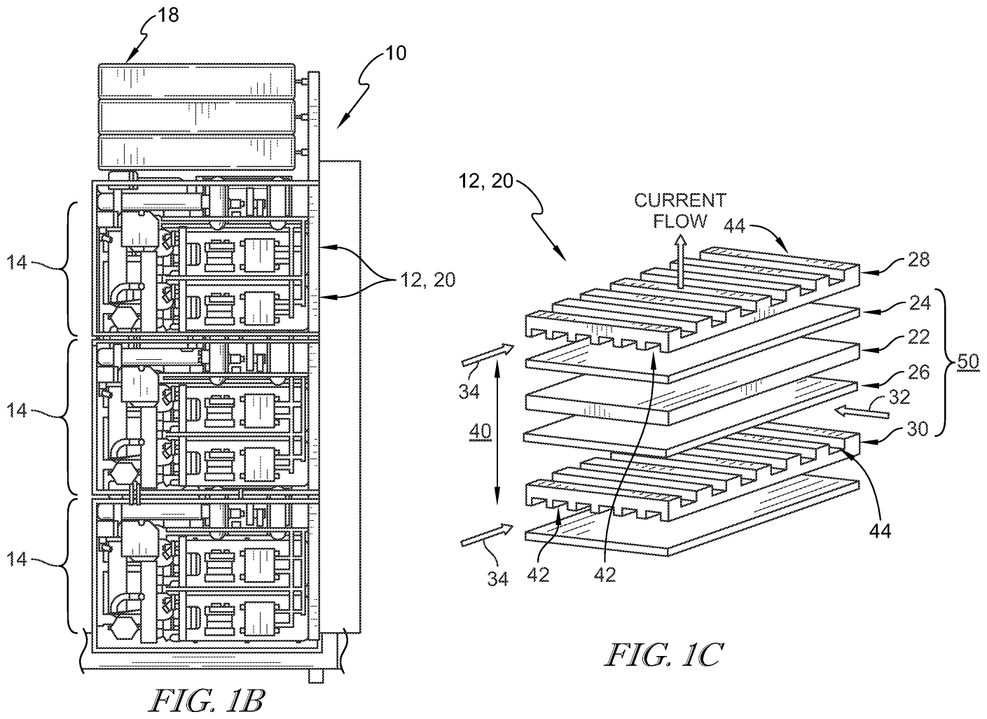

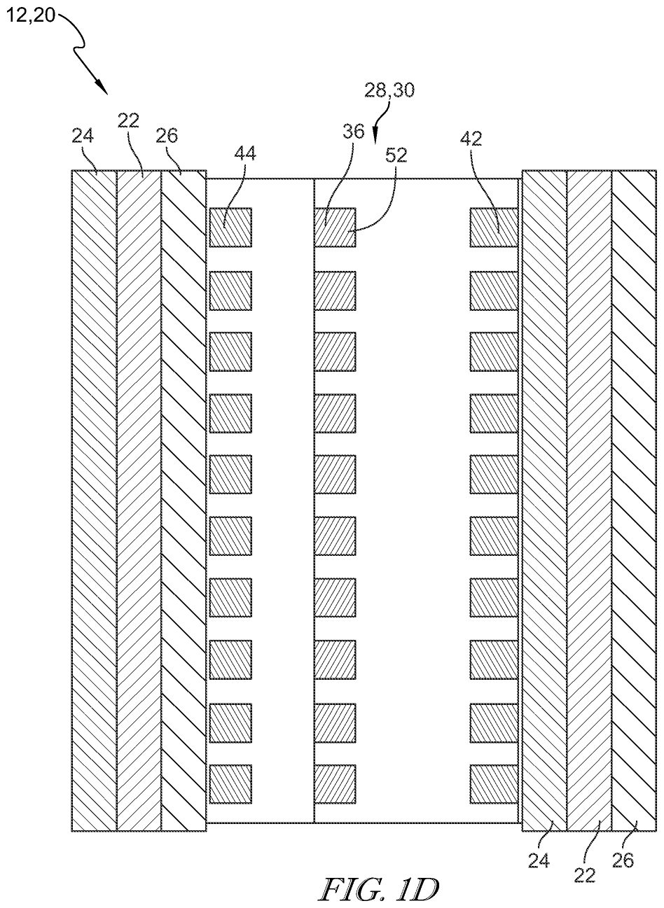

As shown in FIG. 1A, fuel cell systems 10 often include one or more fuel cell stacks 12 or fuel cell modules 14 connected to a balance of plant (BOP) 16, including various components, to support the electrochemical conversion, generation, and/or distribution of electrical power to help meet modern day industrial and commercial needs in an environmentally friendly way. As shown in FIGS. 1B and 1C, fuel cell systems 10 may include fuel cell stacks 12 comprising a plurality of individual fuel cells 20. Each fuel cell stack 12 may house a plurality of fuel cells 20 assembled together in series and/or in parallel. The fuel cell system 10 may include one or more fuel cell modules 14 as shown in FIGS. 1A and 1B.

Each fuel cell module 14 may include a plurality of fuel cell stacks 12 and/or a plurality of fuel cells 20. The fuel cell module 14 may also include a suitable combination of associated structural elements, mechanical systems, hardware, firmware, and/or software that is employed to support the function and operation of the fuel cell module 14. Such items include, without limitation, piping, sensors, regulators, current collectors, seals, and insulators.

The fuel cells 20 in the fuel cell stacks 12 may be stacked together to multiply and increase the voltage output of a single fuel cell stack 12. The number of fuel cell stacks 12 in a fuel cell system 10 can vary depending on the amount of power required to operate the fuel cell system 10 and meet the power need of any load. The number of fuel cells 20 in a fuel cell stack 12 can vary depending on the amount of power required to operate the fuel cell system 10 including the fuel cell stacks 12.

The number of fuel cells 20 in each fuel cell stack 12 or fuel cell system 10 can be any number. For example, the number of fuel cells 20 in each fuel cell stack 12 may range from about 100 fuel cells to about 1000 fuel cells, including any specific number or range of number of fuel cells 20 comprised therein (e.g., about 200 to about 800). In an embodiment, the fuel cell system 10 may include about 20 to about 1000 fuel cells stacks 12, including any specific number or range of number of fuel cell stacks 12 comprised therein (e.g., about 200 to about 800). The fuel cells 20 in the fuel cell stacks 12 within the fuel cell module 14 may be oriented in any direction to optimize the operational efficiency and functionality of the fuel cell system 10.

The fuel cells 20 in the fuel cell stacks 12 may be any type of fuel cell 20. The fuel cell 20 may be a polymer electrolyte membrane or proton exchange membrane (PEM) fuel cell, an anion exchange membrane fuel cell (AEMFC), an alkaline fuel cell (AFC), a molten carbonate fuel cell (MCFC), a direct methanol fuel cell (DMFC), a regenerative fuel cell (RFC), a phosphoric acid fuel cell (PAFC), or a solid oxide fuel cell (SOFC). In an exemplary embodiment, the fuel cells 20 may be a polymer electrolyte membrane or proton exchange membrane (PEM) fuel cell or a solid oxide fuel cell (SOFC).

In an embodiment shown in FIG. 1C, the fuel cell stack 12 includes a plurality of proton exchange membrane (PEM) fuel cells 20. Each fuel cell 20 includes a single membrane electrode assembly (MEA) 22 and a gas diffusion layers (GDL) 24, 26 on either or both sides of the membrane electrode assembly (MEA) 22 (see FIG. 1C). The fuel cell 20 further includes a bipolar plate (BPP) 28, 30 on the external side of each gas diffusion layers (GDL) 24, 26, as shown in FIG. 1C. The above-mentioned components, in particular the bipolar plate 30, the gas diffusion layer (GDL) 26, the membrane electrode assembly (MEA) 22, and the gas diffusion layer (GDL) 24 comprise a single repeating unit 50.

The bipolar plates (BPP) 28, 30 are responsible for the transport of reactants, such as fuel 32 (e.g., hydrogen) or oxidant 34 (e.g., oxygen, air), and cooling fluid 36 (e.g., coolant and/or water) in a fuel cell 20. The bipolar plates (BPP) 28, 30 can uniformly distribute reactants 32, 34 to an active area 40 of each fuel cell 20 through oxidant flow fields 42 and/or fuel flow fields 44 formed on outer surfaces of the bipolar plates (BPP) 28, 30. The active area 40, where the electrochemical reactions occur to generate electrical power produced by the fuel cell 20, is centered, when viewing the stack 12 from a top-down perspective, within the membrane electrode assembly (MEA) 22, the gas diffusion layers (GDL) 24, 26, and the bipolar plate (BPP) 28, 30.

The bipolar plates (BPP) 28, 30 may each be formed to have reactant flow fields 42, 44 formed on opposing outer surfaces of the bipolar plate (BPP) 28, 30, and formed to have coolant flow fields 52 located within the bipolar plate (BPP) 28, 30, as shown in FIG. 1D. For example, the bipolar plate (BPP) 28, 30 can include fuel flow fields 44 for transfer of fuel 32 on one side of the plate 28, 30 for interaction with the gas diffusion layer (GDL) 26, and oxidant flow fields 42 for transfer of oxidant 34 on the second, opposite side of the plate 28, 30 for interaction with the gas diffusion layer (GDL) 24. As shown in FIG. 1D, the bipolar plates (BPP) 28, 30 can further include coolant flow fields 52 formed within the plate (BPP) 28, 30, generally centrally between the opposing outer surfaces of the plate (BPP) 28, 30. The coolant flow fields 52 facilitate the flow of cooling fluid 36 through the bipolar plate (BPP) 28, 30 in order to regulate the temperature of the plate (BPP) 28, 30 materials and the reactants. The bipolar plates (BPP) 28, 30 are compressed against adjacent gas diffusion layers (GDL) 24, 26 to isolate and/or seal one or more reactants 32, 34 within their respective pathways 44, 42 to maintain electrical conductivity, which is required for robust operation of the fuel cell 20 (see FIGS. 1C and 1D).

The fuel cell system 10 described herein, may be used in stationary and/or immovable power system, such as industrial applications and power generation plants. The fuel cell system 10 may also be implemented in conjunction with an air delivery system 18. Additionally, the fuel cell system 10 may also be implemented in conjunction with a hydrogen delivery system and/or a source of hydrogen 19 such as a pressurized tank, including a gaseous pressurized tank, cryogenic liquid storage tank, chemical storage, physical storage, stationary storage, an electrolysis system, or an electrolyzer. In one embodiment, the fuel cell system 10 is connected and/or attached in series or parallel to a hydrogen delivery system and/or a source of hydrogen 19, such as one or more hydrogen delivery systems and/or sources of hydrogen 19 in the BOP 16 (see FIG. 1A). In another embodiment, the fuel cell system 10 is not connected and/or attached in series or parallel to a hydrogen delivery system and/or a source of hydrogen 19.

The present fuel cell system 10 may also be comprised in mobile applications. In an exemplary embodiment, the fuel cell system 10 is in a vehicle and/or a powertrain 100. A vehicle 100 comprising the present fuel cell system 10 may be an automobile, a pass car, a bus, a truck, a train, a locomotive, an aircraft, a light duty vehicle, a medium duty vehicle, or a heavy-duty vehicle. Type of vehicles 100 can also include, but are not limited to commercial vehicles and engines, trains, trolleys, trams, planes, buses, ships, boats, and other known vehicles, as well as other machinery and/or manufacturing devices, equipment, installations, among others.

The vehicle and/or a powertrain 100 may be used on roadways, highways, railways, airways, and/or waterways. The vehicle 100 may be used in applications including but not limited to off highway transit, bobtails, and/or mining equipment. For example, an exemplary embodiment of mining equipment vehicle 100 is a mining truck or a mine haul truck.

In addition, it may be appreciated by a person of ordinary skill in the art that the fuel cell system 10, fuel cell stack 12, and/or fuel cell 20 described in the present disclosure may be substituted for any electrochemical system, such as an electrolysis system (e.g., an electrolyzer), an electrolyzer stack, and/or an electrolyzer cell (EC), respectively. As such, in some embodiments, the features and aspects described and taught in the present disclosure regarding the fuel cell system 10, stack 12, or cell 20 also relate to an electrolyzer, an electrolyzer stack, and/or an electrolyzer cell (EC). In further embodiments, the features and aspects described or taught in the present disclosure do not relate, and are therefore distinguishable from, those of an electrolyzer, an electrolyzer stack, and/or an electrolyzer cell (EC).

Accordingly, the fuel cell system 10 of the present disclosure may include one or more fuel cell modules 14 and/or one or more fuel cell stacks 12 that generate power in a manner far more environmentally friendly than conventional power systems, such as, an internal combustion engine (ICE). The fuel cell system 10, the one or more fuel cell modules 14, and/or the one or more fuel cell stacks 12 of the present disclosure may comprise one or more fuel cells 20. The fuel cell 20 or the one or more fuel cell modules 14 produces electricity by electrochemically combining the fuel 32 and the oxidant 34 across the bipolar plates (BPP) 28, 30.

Fuel cells 20 may be electrically coupled in series into assemblies (e.g., fuel cell stacks 12) to produce power at useful voltages or currents. Therefore, interconnected structures are used to connect or couple adjacent fuel cells 20 in series or in parallel to form a fuel cell stack 12 or a fuel cell module 14. Hardware components used to incorporate an MEA 22 into a fuel cell 20 include gaskets, which provide a seal around the MEA 22 to prevent leakage of gases, and bipolar plates 28, 30, which are used to assemble individual fuel cells 20 into a fuel cell stack 12 and provide channels for the gaseous fuel 32 and air 34.

The fuel cell system 10 may include the balance of plant (BOP) 16. In one example, components of the fuel cell system 10 may be configured to couple to the BOP 16. In another example, the fuel cell system 10 may include additional components, features, or systems to operate valves and other components to control pressure (e.g., fluid or air pressure), heating and cooling, water condensation, temperature, exhaust, humidity, and other operating parameters of the fuel cell system 10. In some embodiments, the BOP 16 of the fuel cell system 10 further comprises one or more valve control systems, fluid control and/or air handling systems, pressure control systems, heating and/or cooling systems, exhaust systems, fuel handling and/or delivery systems, temperature, water, and/or humidity control systems, and wiring and/or electronic systems, including external power electronics systems.

A typical duty cycle of the mining equipment vehicle 100 includes periods of high power load, e.g., when the vehicle 100 is climbing an incline and/or hauling a full payload, and periods of low power load, e.g., when the vehicle 100 is traveling downhill and/or traveling empty. As in mining, power load of the vehicle 100 in power generation applications may vary significantly during a given operating cycle. However, without adequate power management, providing sufficient power to such high capacity vehicles 100 that operate under highly variable power loads may require oversizing a battery system by providing additional, or larger, battery packs 158, which, in turn, may increase vehicle 100 fuel consumption and other inefficiencies.

The systems and methods of the present disclosure provide effective management of one or more of the plurality of onboard fuel cell modules 14 to charge the plurality of battery packs 158 of the fuel cell vehicle 100 during different operating states of the vehicle 100. While the present system and method may be used at any time of operation, exemplary operation states of the vehicle 100 where the present system and method may be utilized includes during an idle operating state, a loading and unloading operating state, and a moving operating state. In this manner, the system is configured to utilize lower demand sections of the route of the vehicle 100 to keep the plurality of battery packs 158 sufficiently charged and ready for when high power is needed. The system is configured to ensure that a charge level of the plurality of battery packs 158 is maintained at a predefined target charge level during predefined operating conditions. Predefined operating conditions occur during conditions of sustained power demand P from the fuel cell vehicle 100 when combined power from both the plurality of fuel cell modules 14 and the plurality of battery packs 158 is needed. As some examples, operating conditions that may demand combined power from both the plurality of fuel cell modules 14 and the plurality of battery packs 158 include sustained acceleration events and long or extended hill climbs.

During normal operation, the fuel cells 20 and the plurality of fuel cell modules 14, such as those used in vehicles 100 and/or powertrains 100, continuously age, degrade, and/or deteriorate over time. Degradation rate may vary between each fuel cell 20, e.g., fuel cells 20 near the edges of the fuel cell module 14 may, in some instances, degrade faster. Such aging, degradation, and deterioration may affect performance of one or more stack components, such as the single membrane electrode assembly 22, the bipolar plates 28, 30, the gas diffusion layers 24, 26. This aging, degradation, and/or deterioration may shorten a useful operating lifecycle of the plurality of fuel cell modules 14 or the fuel cell stack 12 as a whole.

Further, certain modes of operation, charge and discharge rates, as well as operating conditions of the fuel cell 20, may accelerate or slow aging and degradation processes within the plurality of fuel cell modules 14. Parameters used to track degradation and aging of the fuel cells 20 may be a state of health (SOH), remaining useful life (RUL), and others. Put another way, a state of performance degradation of a given fuel cell module 14 or a portion of a fuel cell module 14 may be referred to, quantitated, and/or measured as a SOH of that fuel cell module 14 or a portion of fuel cell module 14.

Where multiple fuel cell stacks 12 and/or fuel cell modules 14 having multiple fuel cell stacks 12 are present, portions (e.g., fuel cells 20, stacks of cells 12) of the fuel cell module 14 or one or more of the plurality of fuel cell modules 14 of the fuel cell vehicle 100 may be replaced at different times and/or may degrade at a different rate. Accordingly, the fuel cell system 10 of a given fuel cell vehicle 100 may include one or more fuel cell modules 14 or portions of the fuel cell modules 14 having different states of performance degradation, or changes in operating efficiency from that of a new unit, such as a different SOH from that of one another.

In mining, power generation, and other applications, the plurality of battery packs 158 of vehicles 100 or systems may include multiple battery packs 158 and/or battery packs 158 having multiple battery modules. In some instances, portions (e.g., cells, modules of cells) of a battery pack 158 or one or more battery packs 158 of the fuel cell vehicle 100 may be replaced at different times, such that a battery energy system of a given fuel cell vehicle 100 may include battery packs 158 or portions of battery packs 158 having different states of performance degradation, or changes in operating efficiency from that of a new unit.

A state of performance degradation of a given battery pack 158 or a portion of a battery pack 158 may be referred to as a SOH of that battery pack 158 or a portion of that battery pack 158. Accordingly, a SOH of a given battery pack 158 or a portion of a battery pack 158 may be different from a corresponding SOH of another battery pack 158 or a portion of a same or a different battery pack 158, e.g., a battery module, and so on. The systems and methods of the present disclosure are configured to correct for differences in the SOH of the plurality of battery packs 158 and/or subcomponents of the battery packs 158, such as modules or cells. For example, adjusting power demand to cause the fuel cell stack 12 to charge battery packs 158 having a SOH less than a threshold, while charging battery packs 158 having a SOH greater than a threshold during regenerative braking.

State of charge (SOC) of the battery packs 158 may be indicative of an amount of electrical energy stored in that battery pack 158 and may be a function of temperature, battery capacitance, and battery internal resistance among other parameters. Ability of the battery pack 158 to receive charge, provide charge (e.g., to discharge), and to maintain charge level may degrade as the battery pack 158 ages. Operating parameters and conditions of the battery pack 158 may affect (either slow or accelerate) aging and degradation process.

For example, preventing over-charge and/or over-discharge and improving the battery utilization rate of the battery pack 158 may minimize, slow, or prevent degradation of the battery cells, battery modules, and/or battery stacks. In some instances, degradation of performance of the battery pack 158 may be prevented or slowed by operating the battery pack 158 at a SOC between a predefined minimum and a predefined maximum SOC, e.g., from about 20% to about 90%, from about 20% to about 95%, from about 25% to about 90%, including any specific or range of percentages comprised therein. Accordingly, if the battery pack 158 is at around 20% SOC, the flow of power from the battery pack 158 should decrease, i.e., power demand P of the vehicle 100 may be met using traction motors 162 until the SOC of the battery pack 158 rises above the 20% threshold.

The systems and methods of the present disclosure are configured to correct for differences in the SOC of the plurality of battery packs 158 and/or subcomponents of the battery packs 158, such as modules or cells. For example, adjusting power demand to cause the fuel cell modules 14 to charge the battery packs 158 having a SOC less than a threshold, while charging the battery packs 158 having a SOC greater than a threshold during regenerative braking. The present systems and methods are described in further detail herein.

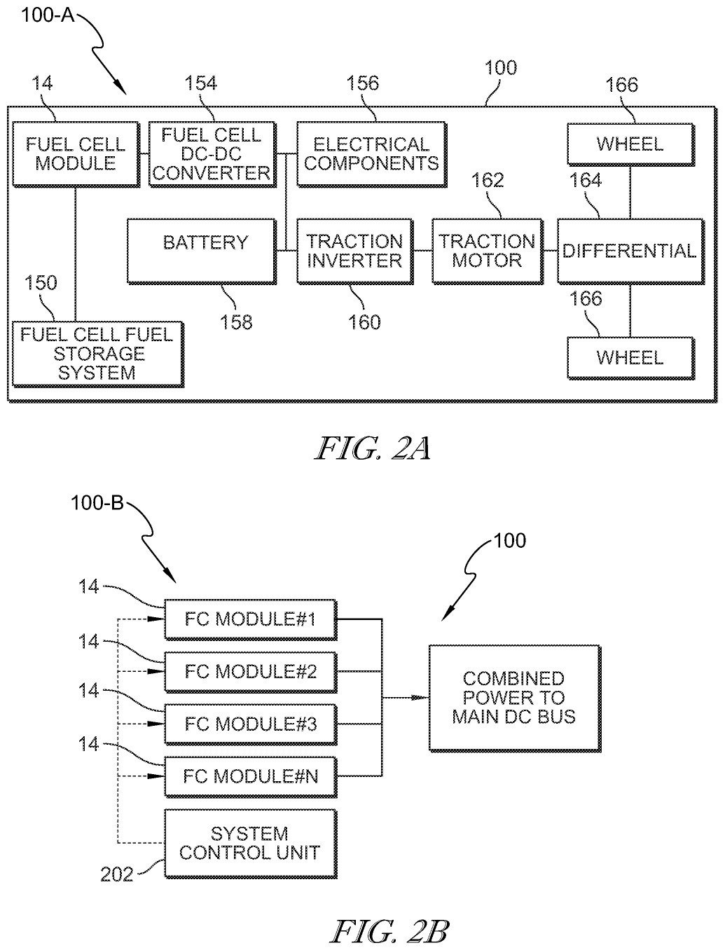

FIG. 2A illustrates an example implementation 100-A of a fuel cell vehicle 100 in accordance with the present disclosure. While the vehicle 100 is illustrated and described in reference to FIG. 2A, the power control systems and methods disclosed herein are not so limited. Example applications of the systems and methods for controlling fuel cell system power flow in accordance with the present disclosure include, but are not limited to, stationary or semi-stationary applications in personal, residential, and/or industrial context. Example non-stationary applications of a humidification system and methods of the present disclosure include vehicular and mobile applications, whether operator-controlled, autonomous, or semi-autonomous, such as, but are not limited to, automobiles, vans, trucks (e.g., mining trucks), agricultural machinery and equipment, trains, marine vehicles, aircraft, spacecraft, satellite, and drone.

The example fuel cell vehicle 100 includes a fuel cell fuel storage system 150, the plurality of fuel cell modules 14, the plurality of battery packs (or battery packs) 158, and/or the traction motor 162. As illustrated in FIG. 2B, an example implementation 100-B of the fuel cell vehicle 100 for specialized off-highway/on-highway applications, such as mining or power generation, may include the plurality of fuel cells 20 interconnected, or otherwise electrically or mechanically combined, to provide the plurality of fuel cell stacks 12, that are, in turn, combined into the plurality of fuel cell modules 14. Additionally or alternatively, the fuel cell vehicle 100 may include the plurality of battery packs 158.

Referring back to FIG. 2A, the fuel cell fuel storage system 150 of the example fuel cell vehicle 100 provides fuel 32 (e.g., hydrogen, compressed natural gas (CNG)) for a fuel cell 20 or fuel cell stack 12 of the plurality of fuel cell modules 14. The plurality of fuel cell modules 14 uses a chemical process to generate electrical energy. The electrical energy generated by the plurality of fuel cell modules 14 may be stored in the plurality of battery packs 158 for use by one or more propulsion or non-propulsion components of the example fuel cell vehicle 100.

In some instances, a portion of the electrical energy generated by the plurality of fuel cell modules 14, whether directly or via the plurality of battery packs 158, may be used to power the traction motor 162 (see FIG. 2A). The traction motor 162 is mechanically coupled to a differential 164 that distributes power to one or more wheels 166 (e.g., about 1 to about 16 wheels) to operate the fuel cell vehicle 100. In still other examples, a portion of the electrical energy generated by the plurality of fuel cell modules 14, whether directly or via the plurality of battery packs 158, may be transferred to power electrical components 156 of the fuel cell vehicle 100, such as interior lighting, cabin cooling, and/or an infotainment system (e.g., TV/console/computer display system).

Referring again to FIG. 2A, a fuel cell DC-DC converter 154 steps up DC power output by the plurality of fuel cell modules 14 to a voltage compatible with the electrical components 156 and/or the plurality of battery packs 158. A traction inverter 160 inverts DC power supplied by the plurality of battery packs 158 and/or by the plurality of fuel cell modules 14 to AC power compatible with the traction motor 162. The traction inverter 160 may be bi-directional and may convert AC power output by the traction motor 162 operating in a generator mode to DC power for transfer to the plurality of battery packs 158.

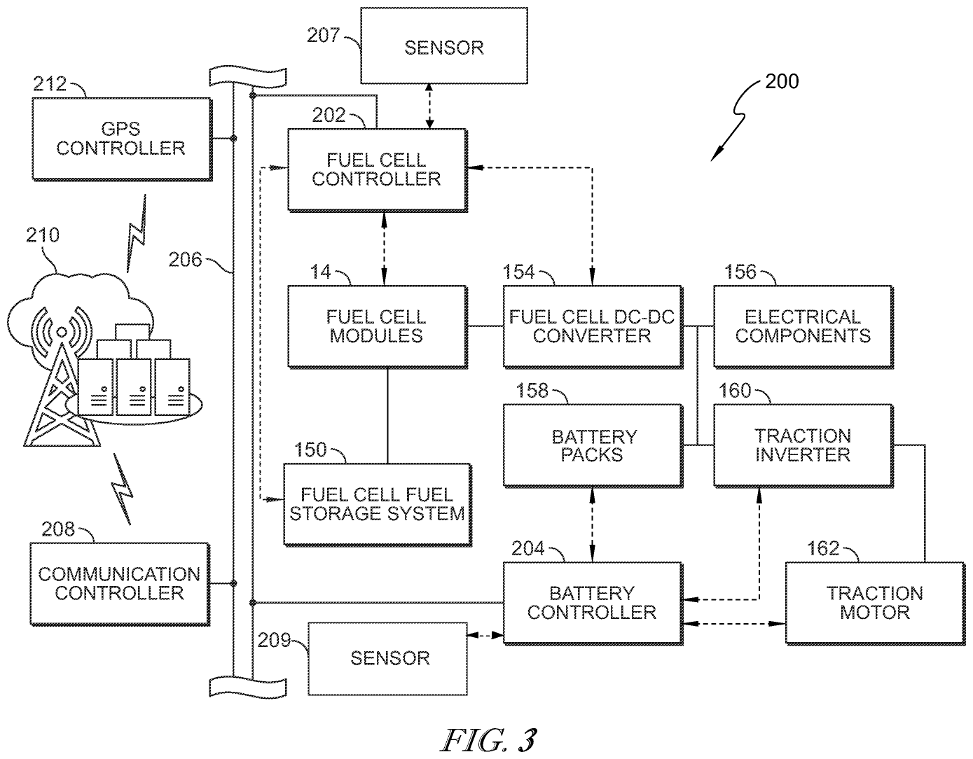

FIG. 3 illustrates an example control system 200 for controlling one or more components of the fuel cell vehicle 100 described in reference to FIG. 2A. The control system 200 includes a fuel cell controller 202 and a battery controller 204. The fuel cell controller 202 may be communicatively coupled to and configured to monitor and control operation of the fuel cell fuel storage system 150, the plurality of fuel cell modules 14, and/or the fuel cell DC-DC converter 154. The battery controller 204 may be communicatively coupled to and configured to monitor and control operation of the plurality of battery packs 158, the traction inverter 160, and/or the traction motor 162.

Of course, in other implementations, one or more operations of the fuel cell controller 202 may be executed by the battery controller 204 and vice versa. In still other examples, one or more operations of the controllers 202, 204 may be executed by one or more other hybrid-vehicle-specific or conventional vehicle controllers, such as, for example, a vehicle system controller, an energy management controller, a regenerative braking controller, and/or an electrical system controller. To that end, the controllers 202, 204 may be communicatively coupled to a vehicle communication network 206 and configured to exchange data, signals, and/or action commands with one another and with other controllers of the vehicle 100.

Each of the fuel cell controller 202 and the battery controller 204 may be communicatively coupled to and configured to receive signals from one or more sensors 207, 209. Sensors 207, 209 may include any type of sensor, for example, temperatures sensors, pressure sensors, current sensors, and/or voltage sensors. The controllers 202, 204 are configured to control, based on one or more of a received sensor signal, operation of one or more components, systems, and/or subsystems of the vehicle 100, such as the fuel cell fuel storage system 150, the plurality of fuel cell modules 14, the fuel cell DC-DC converter 154, the plurality of battery packs 158, the traction inverter 160, and/or the traction motor 162, as just some examples.

The vehicle 100 may include a communication controller 208 configured to establish communication between the vehicle 100 and a network 210. The communication controller 208 may be configured to communicate via the network 210, either periodically or in response to a corresponding signal from a controller 202, 204 of the vehicle 100, to transmit and receive data indicating a vehicle operating state, vehicle lookahead data, and/or other information. The vehicle 100 may include a global positioning system (GPS) controller 212 configured to establish communication via the network 210 to receive geographic coordinates or other environmental or location information of the vehicle 100.

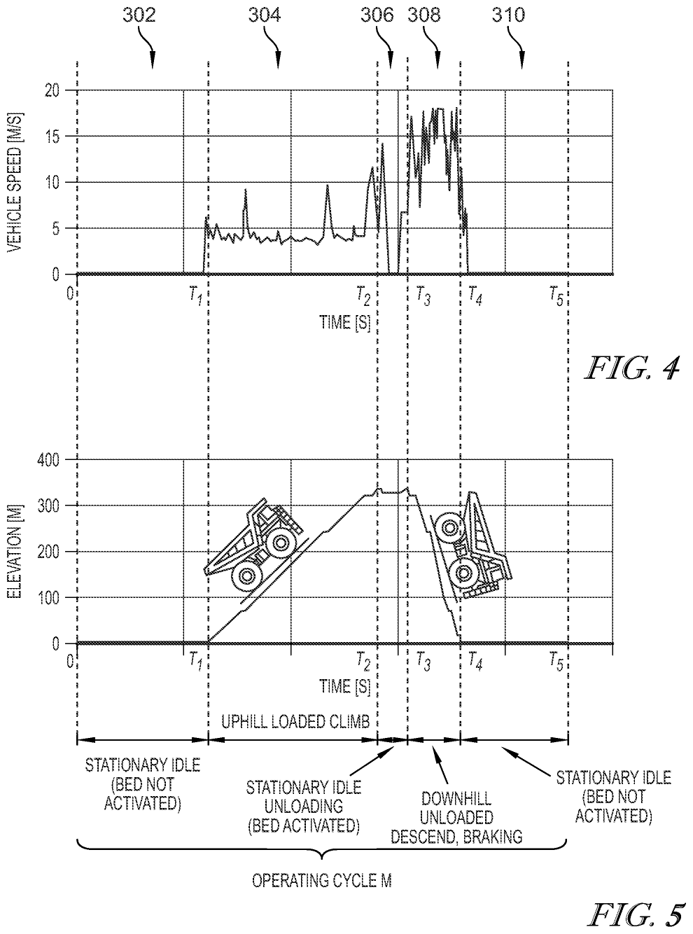

FIG. 4 is a graph illustrating a change in speed of the fuel cell vehicle 100 with respect to time during an example operating cycle M. FIG. 5 is a graph illustrating a change in elevation of the fuel cell vehicle 100 with respect to time during the example operating cycle M. The example operating cycle M of the vehicle 100 may include a first stationary idle loading phase 302, an uphill loaded climbing phase 304, a stationary idle unloading phase 306, a downhill unloaded descending phase 308, and/or a second stationary idle loading phase 310. In some instances, phases 302, 304, 306, 308, 310 of the operating cycle M may be arranged in a different order or sequence or may be repeated. In some other instances, the operating cycle M may include fewer, more, or a different combination of phases.

The fuel cell vehicle 100 may be said to be in one of the first and second stationary idle loading phases 302, 310 when the vehicle 100 is stationary, idling, and, if equipped with a truck bed, having an inactive truck bed, i.e., from a time t₀ to a time t₁ and from a time t₄ to a time t₅ of the graphs of FIGS. 4 and 5, respectively. Whether the fuel cell vehicle 100 is stationary may be determined based on, for example, at least one of a transmission gear position, a speed of the vehicle 100, and/or a speed of the wheel 166 of the vehicle 100. Whether the fuel cell vehicle 100 is idling may be determined based on, for example, at least one of an ignition switch position, a transmission gear position, and/or a speed of the traction motor 162. Whether a truck bed of the fuel cell vehicle 100 is inactive may be determined based on, for example, a position of the truck bed, a speed of the truck bed, and/or a positon of a switch controlling the truck bed.

The fuel cell vehicle 100 may be said to be in the uphill loaded climbing phase 304 when the vehicle 100 is moving up an incline with a predefined payload, i.e., from a time t₁ to a time t₂ of the graphs of FIGS. 4 and 5. Whether the fuel cell vehicle 100 is moving may be determined based on, for example, at least one of a transmission gear position, a speed of the vehicle 100, and/or an acceleration of the vehicle 100. Whether the fuel cell vehicle 100 is traveling up an incline may be determined based on, for example, at least one of a change in elevation of the vehicle 100, a power load of the traction motor 162, and a speed and acceleration of the vehicle 100. Whether the fuel cell vehicle 100 is carrying a payload may be determined based on, for example, a weight of the vehicle 100, a power load of the traction motor 162, and/or a speed and acceleration of the vehicle 100.

The fuel cell vehicle 100 may be said to be in the stationary idle unloading phase 306 when the vehicle 100 is stationary, idling, and, if equipped with a truck bed, the truck bed of the vehicle 100 being active, i.e., from a time t₂ to a time t₃ of the graphs of FIGS. 4 and 5. Whether the fuel cell vehicle 100 is stationary may be determined based, for example, on at least one of a transmission gear position, a speed of the vehicle 100, and a speed of the wheel 166 of the vehicle 100. Whether the fuel cell vehicle 100 is idling may be determined based on, for example, at least one of an ignition switch position, a transmission gear position, and/or a speed of the traction motor 162. Whether a truck bed of the fuel cell vehicle 100 is active may be determined based on, for example, a position of the truck bed, a speed of the truck bed, and/or a positon of a switch controlling the truck bed.

The fuel cell vehicle 100 may be said to be in the downhill unloaded descending phase 308 when the vehicle 100 is moving down an incline without a payload, i.e., from a time t₃ to a time t₄ of the graphs of FIGS. 4 and 5. Whether the fuel cell vehicle 100 is moving may be determined based on, for example, at least one of a transmission gear position, a speed of the vehicle 100, and/or an acceleration of the vehicle 100. Whether the fuel cell vehicle 100 is traveling down an incline may be determined based on, for example, at least one of a change in elevation of the vehicle 100, a power load of the traction motor 162, and/or a speed and acceleration of the vehicle 100. Whether the fuel cell vehicle 100 is carrying a payload may be determined based on, for example, a weight of the vehicle 100, a power load of the traction motor 162, and/or a speed and acceleration of the vehicle 100.

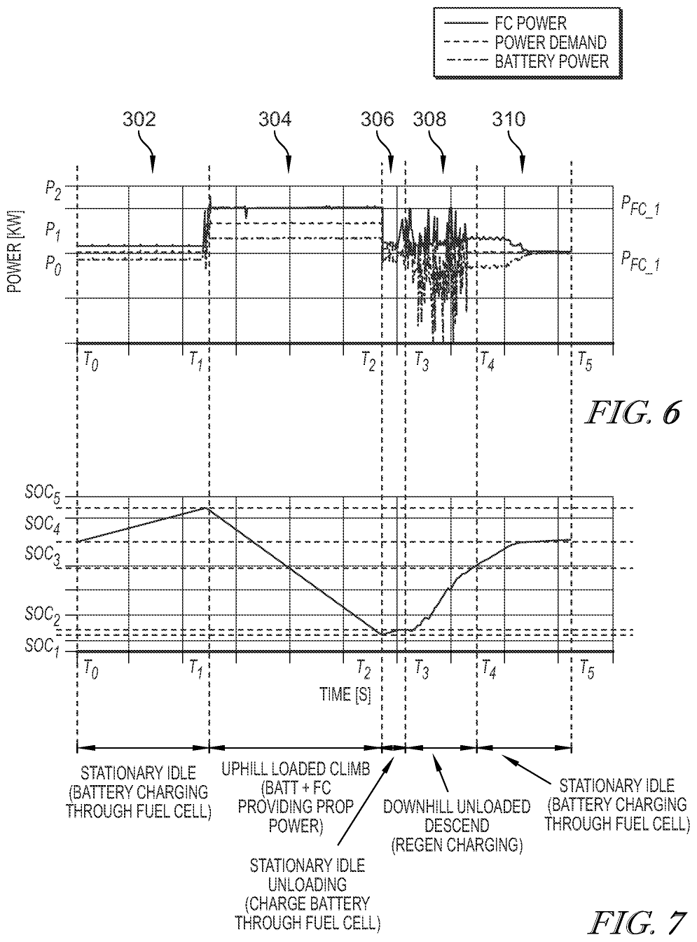

FIG. 6 is a graph illustrating a flow of power from the plurality of fuel cell modules 14 to and from the plurality of battery packs 158 of the fuel cell vehicle 100 with a change in power demand P of the vehicle 100 during each of the phases 302, 304, 306, 308, 310 of the example operating cycle M. FIG. 7 is a graph illustrating a change in the SOC of the plurality of battery packs 158 of the fuel cell vehicle 100 during each of the phases 302, 304, 306, 308, 310 of the example operating cycle M. The SOC of the plurality of battery packs 158 depends on the battery chemistry of a particular battery pack 158.

In one example, a power demand P of the vehicle 100 may be between about 0 kW and about 100 kW, including any specific or range of kW comprised therein, during the first stationary idle loading phase 302. As shown in FIG. 7, the fuel cell controller 202 may cause the plurality of fuel cell modules 14 to charge the plurality of battery packs 158 during the first stationary idle loading phase 302 to increase the SOC of the battery packs 158 from SOC₄ to SOC₅.

As another example (see FIGS. 6 and 7), a power demand P of the vehicle 100 may be greater than or equal to about 1200 kW during the uphill loaded climbing phase 304. The fuel cell controller 202 and the battery controller 204 may be configured to cause the plurality of fuel cell modules 14 and the plurality of battery packs 158 to provide energy to achieve the power demand value P₂. The SOC of the plurality of battery packs 158 may decrease from SOC₅ to SOC₁ during the uphill loaded climbing phase 304.

As still another example, a power demand P of the vehicle 100 may be between about 300 kW and about 1200 kW, including any specific or range of kW comprised therein, during the stationary idle unloading phase 306. The fuel cell controller 202 may be configured to cause the plurality of fuel cell modules 14 to charge the plurality of battery packs 158 during the stationary idle unloading phase 306 to increase the SOC of the plurality of battery packs 158 from SOC₁ to SOC₂.

As yet another example, a power demand P of the vehicle 100 may be between about 0 kW and about 300 kW, including any specific or range of kW comprised therein, during the downhill unloaded descending phase 308. The fuel cell controller 202 may cause the plurality of fuel cell modules 14 to charge the plurality of battery packs 158 during the downhill unloaded descending phase 308 to increase the SOC of the plurality of battery packs 158 from SOC₂ to SOC₃.

As still another example, a power demand P of the vehicle 100 may be between about 0 kW and about 100 kW, including any specific or range of kW comprised therein, during the second stationary idle loading phase 310. The fuel cell controller 202 may cause the plurality of fuel cell modules 14 to charge the plurality of battery packs 158 to increase the SOC of the plurality of battery packs 158 from SOC₃ to SOC₄ during the second stationary idle loading phase 310 (see FIGS. 6 and 7).

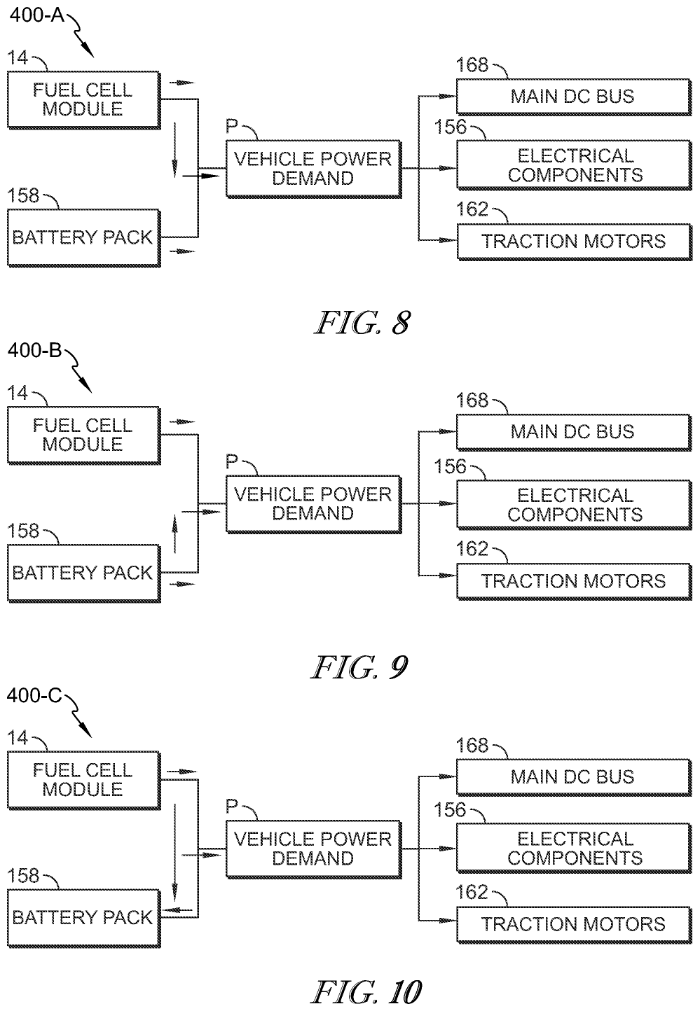

FIGS. 8-10 illustrate diagrams of power control strategies that may be applied in response to a change in power demand P of the vehicle 100 during each of the phases 302, 304, 306, 308, 310 of the example operating cycle M.

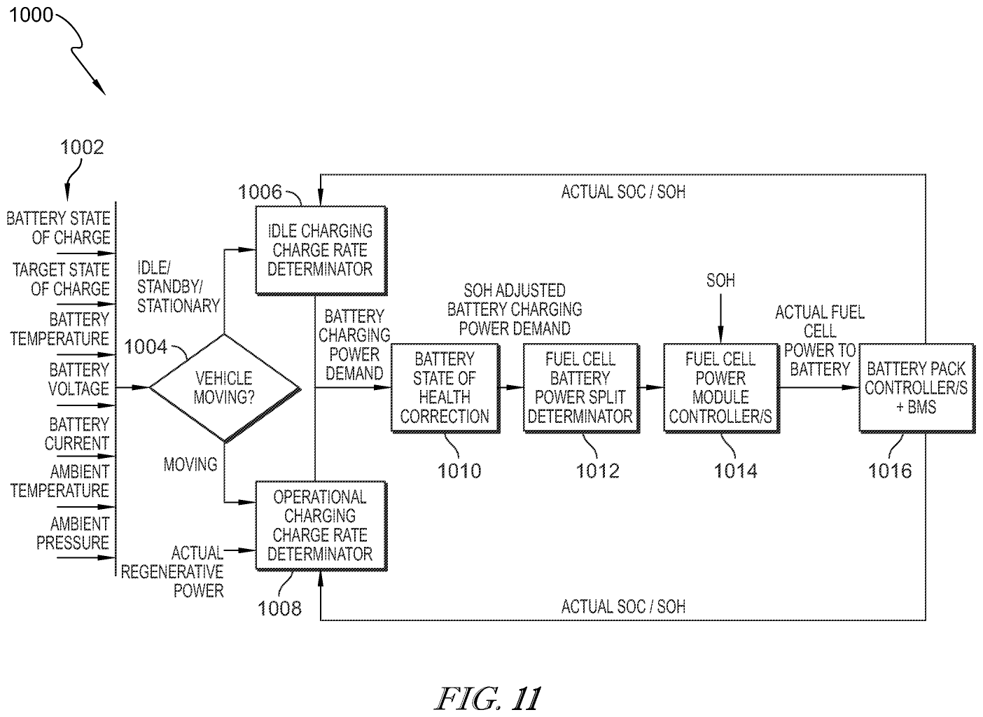

In response to power demand P of the vehicle 100 being less than a predefined threshold (between about 0 kW and about 100 kW, including any specific or range of kW comprised therein) during the first and second stationary idle loading phases 302, 310 discussed in reference to at least FIGS. 4-7, the fuel cell controller 202 and the battery controller 204 may be configured to operate the plurality of fuel cell modules 14 and the plurality of battery packs 158, respectively. The controllers 202, 204 may be configured to utilize at least one of a first strategy 400-A, as shown in FIG. 8, a second strategy 400-B, as shown in FIG. 9, and/or a third strategy 400-C, as shown in FIG. 10.

More specifically, the first strategy 400-A of the fuel cell controller 202 includes transferring power from the fuel cell modules 14 to the traction motor 162, e.g., via the traction inverter 160 as shown in FIG. 8. This first strategy is implemented to achieve the power demand P of the vehicle 100, turn down or decrease the use of the plurality of battery packs 158 due to the SOC of the plurality of battery packs 158 being less than a predefined threshold, and/or to conserve the SOH of the plurality of battery packs 158. In some instances, turning down or decreasing the use of the plurality of battery packs 158 may include turning off, or otherwise temporarily disabling or inhibiting operation of the plurality of battery packs 158. This decreased or disabled use of the battery packs ensures that the SOC of the plurality of battery packs 158 is maintained at the predefined threshold, e.g., such that the SOC of the plurality of battery packs 158 is between about 20% and about 100%, including any specific or range of percentages comprised therein.

In this manner, an excessive rate of degradation of the plurality of battery packs 158 may be prevented or slowed. In some instances, to help manage, reduce, and/or prevent the degradation rate of the plurality of battery packs 158 to achieve longevity of the operation of the plurality of battery packs 158, the plurality of battery packs 158 may be designed to operate at a SOC between about 20% and about 90%, including any specific or range of percentages comprised therein. Accordingly, if the plurality of battery packs 158 is at about 20% SOC, the flow of power from the plurality of battery packs 158 should decrease, i.e., power demand P of the vehicle 100 may be met using the plurality of fuel cell modules 14 and traction motors 162 until the SOC of the plurality of battery packs 158 is sufficiently above the 20% threshold.

The second strategy 400-B applied by the fuel cell controller 202 and the battery controller 204 during the first and second stationary idle loading phases 302, 310 is shown in FIG. 9. This second strategy 400-B includes causing the plurality of battery packs 158 to provide power to the traction motors 162 and to the vehicle 100 while turning down the use of the plurality of fuel cell modules 14 to conserve fuel cell fuel 32 (e.g., hydrogen) to optimize fuel economy.

The third strategy 400-C of the fuel cell controller 202 that may be applied during the first and second stationary idle loading phases 302, 310 is shown in FIG. 10. This third strategy 400-C includes transferring power from the plurality of fuel cell modules 14 to the plurality of battery packs 158 and the traction motors 162, such that a higher fuel cell 20 power may be used to charge the plurality of battery packs 158 to maintain a target SOC operation, while at the same time providing power to the vehicle 100.

Moreover, the control strategy and power flow 400-A described with reference to FIG. 8 may be applied in response to power demand P of the vehicle 100 being between about 300 kW and about 1200 kW, including any specific or range of kW comprised therein, such as during the stationary idle unloading phase 306 discussed in reference to at least FIGS. 4-7 and/or during traveling on a level (flat) grade. In addition to the first, second, and third control strategies 400-A, 400-B, 400-C described above, respectively, in reference to the vehicle 100 operating in the first and second stationary idle loading phases 302, 310, the fuel cell controller 202 may apply a fourth control strategy during the stationary idle unloading phase 306 and/or during traveling on a level (flat) grade. The fourth control strategy may include causing both the plurality of fuel cell modules 14 and the plurality of battery packs 158 to provide power to the traction motor 162 to actuate the truck bed during unloading. Alternatively, this fourth control strategy may be utilized to propel the vehicle 100 traveling on a level grade and may improve maintaining a target SOC and a target SOH for components of the fuel cell vehicle 100.

With reference to FIG. 9, in response to power demand P of the vehicle 100 being greater than or equal to about 1200 kW, during the uphill loaded climbing phase 304 discussed in reference to at least FIGS. 4-7, the fuel cell controller 202 and the battery controller 204 may be configured to operate the plurality of fuel cell modules 14 and the plurality of battery packs 158, respectively, to maintain a target SOC and a target SOH for components of the fuel cell vehicle 100.

With reference to FIG. 10, in response to power demand P of the vehicle 100 being between about 0 kW and about 100 kW, including any specific or range of kW comprised therein, and/or braking power being between about 0 kW and about 3000 kW, including any specific or range of kW comprised therein, such as during the downhill unloaded descending phase 308 discussed in reference to at least FIGS. 4-7, the fuel cell controller 202 and the battery controller 204 may be configured to operate the plurality of fuel cell modules 14 and the plurality of battery packs 158, respectively, to cause the traction motor 162 to transfer regenerative braking energy to the plurality of battery packs 158. In response to capturing all available regenerative braking energy in the plurality of battery packs 158, the fuel cell controller 202 may be configured to initiate or resume transferring energy from the plurality of fuel cell modules 14 to charge the plurality of battery packs 158.

Other example operating states of the fuel cell vehicle 100 include a cold start operating state such as when the vehicle 100 operates in ambient temperature less than a predefined threshold temperature requiring an additional heating load and, thus, causing an increase in power demand on the plurality of fuel cell modules 14 and the plurality of battery packs 158. As another example, activating a component protection mode such as, for example, initiating a hot shutdown to turn off power components, may, nevertheless, require the plurality of fuel cell modules 14 and/or the plurality of battery packs 158 to provide power to cool these power components and other components of the vehicle 100. As still another example, additional charging of the plurality of battery packs 158 may be needed through the plurality of fuel cell modules 14 while the vehicle 100 is in an off state. As yet another example, test modes may be incorporated to test component health that would impact the power flows especially as it relates to the vehicle 100 power demand P and load bank demand.

FIG. 11 illustrates an example power control system 1000 in accordance with the present disclosure. One or more operations of the control system 1000 may be executed by at least one of the fuel cell controller 202 and the battery controller 204. Inputs 1002 to the control system 1000 of FIG. 11 include, for example, battery state of charge, target state of charge, battery temperature, battery voltage, battery current, ambient temperature, and/or ambient pressure. These inputs 1002 are inputs for at least one of the fuel cell controller 202 and the battery controller 204.

At block 1004, at least one of the fuel cell controller 202 and the battery controller 204 determine an operational state of the vehicle 100. If the vehicle 100 is idle, standby, or stationary, at block 1006, the at least one of the fuel cell controller 202 and the battery controller 204 determines a battery charge rate for charging the plurality of battery packs 158 while the vehicle 100 is idle, in standby, or stationary. The battery charge rate corresponds to the battery charging power demand. Block 1006 has an input of the SOC and SOH of the plurality of battery packs 158. The SOH of the plurality of battery packs 158 is an input because, based on the SOH, a different charge rate and power demand may be used to extend the health of the plurality of battery packs 158. A lookup table or a relational model may be used at block 1006 to determine the charge rate of the plurality of battery packs 158 with various SOCs and SOHs corresponding to charge rates.

If the vehicle 100 is determined to be moving at block 1004, then at block 1008, a battery charge rate for charging the plurality of battery packs 158 while the vehicle 100 is moving is determined. Block 1008 has an input of the SOC and SOH of the plurality of battery packs 158 and an actual regenerative power. The actual regenerative power is indicative of how much regenerative braking energy the traction motor 162 can transfer to the plurality of battery packs 158.

For example, if the vehicle 100 is going down a hill, there may be regenerative power available for the plurality of battery packs 158 to use. As another example, if the vehicle 100 is going up a hill, there may be no regenerative power available for the plurality of battery packs 158 to use. The SOH of the plurality of battery packs 158 is an input because, based on the SOH, a different charge rate and power demand may be used to extend the health of the plurality of battery packs 158. A lookup table or a relational model may be used at block 1008 to determine the charge rate of the plurality of battery packs 158 with various SOCs and SOHs and values of actual regenerative power corresponding to charge rates. The battery charge rate corresponds to the battery charging power demand from the plurality of fuel cell modules 14.

At block 1010, the at least one of the fuel cell controller 202 and the battery controller 204 corrects the plurality of battery packs 158 SOH by adjusting the power demand from the fuel cell modules 14 to charge the plurality of battery packs 158 to ensure the SOH of the plurality of battery packs 158 is not compromised. At block 1012, the at least one of the fuel cell controller 202 and the battery controller 204 determines a power split between the fuel cell modules 14 and the plurality of battery packs 158. At least one of the fuel cell controller 202 and the battery controller 204 determines the power split based on at least one of the SOH of the plurality of battery packs 158, the SOH of the plurality of fuel cell modules 14, and the SOC of the plurality of battery packs 158.

At block 1014, the fuel cell controller 202 operates the fuel cell modules 14 to provide power to the plurality of battery packs 158 to meet the power demand of the plurality of battery packs 158 based on the power split determined in block 1012. The SOH of the plurality of fuel cell modules 14 may be used as an input to block 1014 to determine which fuel cell module(s) 14 will be used to charge the plurality of battery packs 158. At block 1016, the battery controller 204 operates the plurality of battery packs 158.

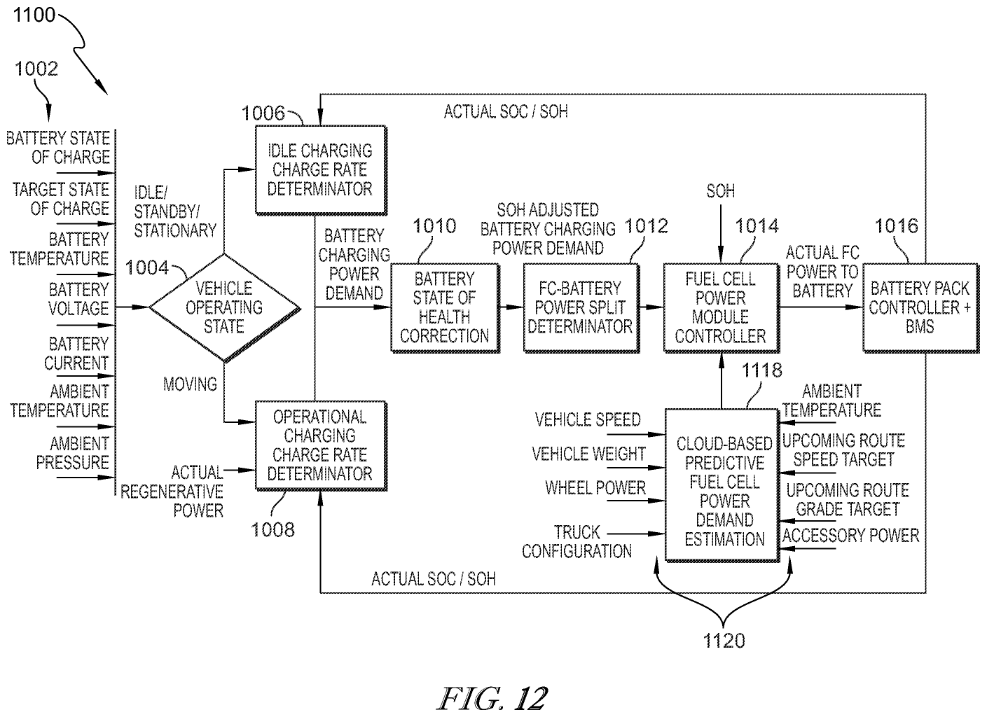

FIG. 12 illustrates another exemplary power control system 1100 configured to communicate with a cloud network 1118 to obtain data therefrom, such as, but not limited to, an estimated predictive fuel cell module power demand value for each fuel cell module 14 of the vehicle 100. Power control system 1100 is identical to power control system 1000 except that power control system 1110 includes a cloud-based predictive fuel cell power demand estimation in block 1118. Inputs 1120 to the cloud network in block 1118 include, for example, a speed of the vehicle 100, a weight of the vehicle 100, a power of the wheel 166, a configuration of the vehicle 100, such as, for example, bed heating, ambient temperature, upcoming route speed target, upcoming route grade target, and/or accessory power.

Inputs 1002 to the control system 1100 of FIG. 12 include, for example, battery state of charge, target state of charge, battery temperature, battery voltage, battery current, ambient temperature, and ambient pressure, among others. The inputs 1002 are inputs for at least one of the fuel cell controller 202 and the battery controller 204. At block 1004, at least one of the fuel cell controller 202 and the battery controller 204 determines the operational state of the vehicle 100. If the vehicle 100 is idle, in standby, or stationary, at block 1006, the at least one of the fuel cell controller 202 and the battery controller 204 determines a battery charge rate for charging the plurality of battery packs 158 while the vehicle 100 is idle, standby, or stationary. Block 1006 has an input of the SOC and SOH of the plurality of battery packs 158. If the vehicle 100 is moving, at block 1008, a battery charge rate for charging the plurality of battery packs 158 while the vehicle 100 is moving is determined. Block 1108 has an input of the SOC and SOH of the plurality of battery packs 158 and the actual regenerative power.

At block 1010, the at least one of the fuel cell controller 202 and the battery controller 204 corrects the plurality of battery packs 158 SOH by adjusting the power demand from the fuel cell modules 14 to charge the plurality of battery packs 158 to ensure the SOH of the plurality of battery packs 158 is not compromised. At block 1012, the at least one of the fuel cell controller 202 and the battery controller 204 determines a power split between the fuel cell modules 14 and the plurality of battery packs 158. At least one of the fuel cell controller 202 and the battery controller 204 determines the power split based on at least one of the SOH of the plurality of battery packs 158, the SOH of the plurality of fuel cell modules 14, and the SOC of the plurality of battery packs 158. At block 1014, the fuel cell controller 202 operates the fuel cell modules 14 to provide power to the plurality of battery packs 158 to meet the power demand of the plurality of battery packs 158. The SOH of the plurality of fuel cell modules 14 may be used as an input to block 1014 to determine which fuel cell module(s) 14 will be used to charge the plurality of battery packs 158.

Block 1014 receives input from block 1118 regarding the estimated predictive fuel cell module power demand value for each fuel cell module 14. For example, block 1118 may determine that a steep hill is in the upcoming route of the vehicle 100, meaning the power demand P of the vehicle 100 will be increasing when the vehicle 100 encounters the hill. To prepare to encounter the hill, the plurality of battery packs 158 will be charged more by the plurality of fuel cell modules 14. The fuel cell controller 202, at block 1014, uses the predictive information from block 1118 to provide power to the plurality of battery packs 158 from the plurality of fuel cell modules 14. At block 1016, the battery controller 204 operates the plurality of battery packs 158.

As described above, an example fuel cell vehicle 100 for specialized off-highway/on-highway applications, such as mining or power generation, may include the plurality of fuel cell modules 14 (that, in turn, may be arranged into the plurality of fuel cell stacks 12) and/or the plurality of battery packs 158. In some instances, portions (e.g., cells, modules of cells) of the battery pack 158 or one or more battery packs 158 of the fuel cell vehicle 100 may be replaced at different times, such that a battery energy system of a given fuel cell vehicle 100 may include battery packs 158 or portions of battery packs 158 that have different ages and, thus, different SOH.

The system of the present disclosure uses dynamic control algorithms to optimize fuel cell 20 operation by controlling the operating point of each fuel cell module 14 individually to achieve a globally optimum fuel consumption (see e.g., FIG. 2B). An example fuel cell module 14 configuration includes a plurality of fuel cell modules 14, each having either the same or different power ratings from one another, being connected to a main DC bus 168 of an electrified powertrain 100. The powertrain 100 connection may be through a DC link connecting the traction motor generators (e.g., the traction motor 162), or through a single motor generator driving transmission and/or axle. Indeed, these arrangements may be applicable to a fuel cell hybrid architecture having a battery in the system.

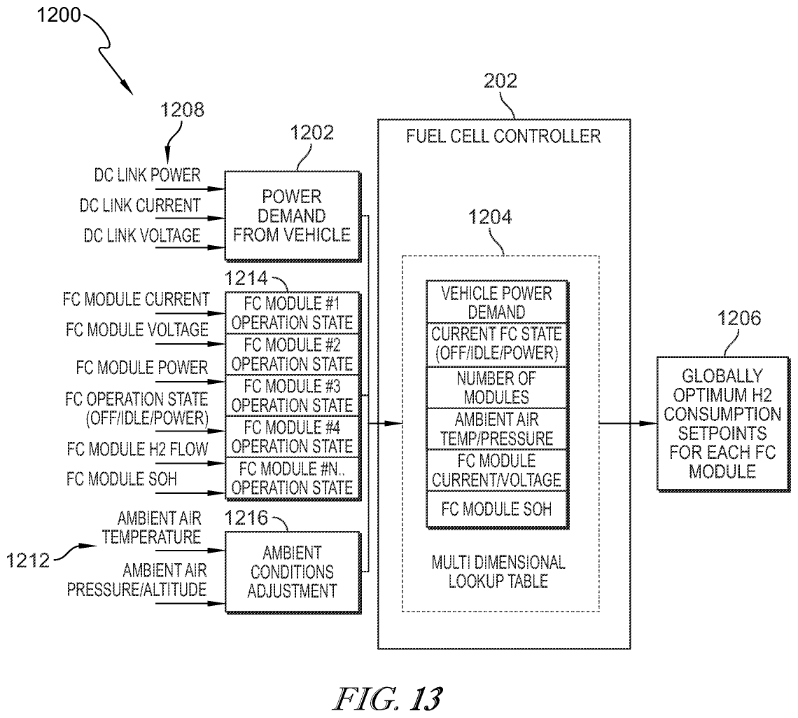

As illustrated in at least FIGS. 13-16, the system of the present disclosure includes the fuel cell controller 202 configured to apply one of an open loop control strategy 1200, a closed loop control strategy 1300, a hybrid control strategy 1400, and/or an additional hybrid control strategy 1500 that includes elements of both the open and closed loop strategies.

FIG. 13 illustrates an example open loop control strategy system 1200 for the fuel cell vehicle 100. In one example, an open loop control strategy may be implemented by the fuel cell controller 202 and may include a split main DC link power demand from the vehicle 100 based on fixed calibration with a multi-dimensional lookup table utilized by an open loop controller 1204. The fuel cell controller 202 includes the open loop controller 1204.

Inputs 1208 are used to determine the power demand P of the vehicle 100 in block 1202. Inputs 1208 include a DC link power, a DC link current, and a DC link voltage. Inputs 1210 are received by block 1214 which determines an operation state of each fuel cell module 14. Inputs 1210 include a current, a voltage, a power, an operation state (off/idle/powered), a SOH, and a fuel flow of each fuel cell module 14. Block 1216 determines changes in ambient conditions. Inputs 1212 of block 1216 include ambient air temperature and ambient air pressure and/or altitude.

Fuel cell controller 202 receives information regarding the power demand P of the vehicle 100 from block 1202, the operation state of each fuel cell module 14 from block 1214, and/or information regarding ambient conditions from block 1216. The fuel cell controller 202 is configured to interpolate values that fall between those available in the lookup table of the open loop controller 1204, where the lookup table may be a calibration set based on detailed test data generation stored in the fuel cell controller 202 during manufacturing. Using the information received from blocks 1202, 1214, and 1216, and the lookup table of the open loop controller 1204, the fuel cell controller 202 determines and outputs an operating point of each fuel cell module 14 individually to achieve a globally optimum fuel consumption in block 1206.

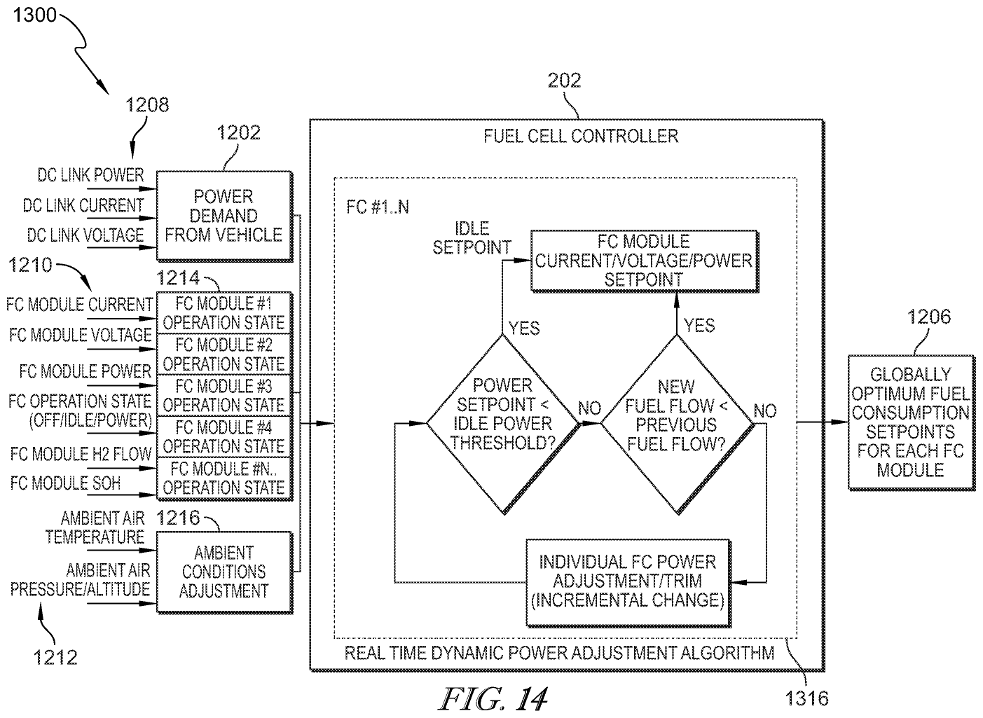

FIG. 14 illustrates an example closed loop control strategy system 1300 in accordance with the present disclosure. In applying a closed loop control strategy, the fuel cell controller 202 is configured to provide a dynamic power demand split into individual fuel cell modules 14 and control power flow to meet an overall system optimum for fuel cell fuel consumption. The closed loop control strategy system 1300 is similar to the open loop control strategy system 1200, except that the closed loop control strategy system 1300 utilizes a closed loop controller 1316 including a real time dynamic power adjustment algorithm instead of the multi-dimensional lookup table of the open loop controller 1204.

Inputs 1208 in applying the closed loop control strategy are the same inputs 1208 as in the open loop control strategy system 1200 (a DC link power, a DC link power current, and a DC link power voltage). Inputs 1208 are used to determine the power demand P of the vehicle 100 in block 1202. Inputs 1210 are received by block 1214 to determine an operation state of each fuel cell module 14. Inputs 1210 include a current, a voltage, a power, an operation state (off/idle/powered), a SOH, and a fuel flow of each fuel cell module 14. Block 1216 determines any changes in ambient conditions. Inputs 1212 of block 1216 include ambient air temperature and ambient air pressure/altitude.

Fuel cell controller 202 receives information regarding the power demand P of the vehicle 100 from block 1202, an operation state of each fuel cell module 14 from block 1214, and information regarding ambient conditions from block 1216. The closed loop controller 1316 uses the real time dynamic power adjustment algorithm to set a current, voltage, and power of each fuel cell module 14 based on real-time data and/or information. Outputs of the closed loop strategy include optimum fuel cell fuel consumption set points 1206 for each fuel cell module 14, such as voltage, current, and power for each fuel cell module 14.

In applying the closed loop strategy, the fuel cell controller 202 may be configured to minimize overall fuel cell fuel consumption, and, at the fuel cell module 14 level, change power levels at each of the modules 14. In this manner, the fuel cell controller 202 is configured to minimize overall system fuel cell fuel consumption by actively changing a power output, e.g., current and voltage, at each of the fuel cell modules 14. Further, during closed loop control, each fuel cell module 14 may be placed in an “idle” operating mode/state in response to a signal or command indicating an increase in power demand P such that overall fuel cell fuel consumption of the vehicle 100 increases.

The closed loop controller 1316 determines a power set point for each fuel cell module 14 based on the information from blocks 1202, 1214, and 1216. Then, the closed loop controller 1316 performs a check on the power set point before outputting a globally optimum fuel consumption set point in block 1206. To determine the globally optimum fuel consumption set point, the closed loop controller 1316 determines whether the power set point is less than an idle power threshold. If the power set point is less than the idle power threshold, the fuel cell module 14 is in an idle state. If the fuel cell module 14 is in the idle state, then the controller 1316 updates the idle power threshold to correspond to the power set point and outputs the globally optimum fuel consumption set point for the fuel cell module 14, corresponding to block 1206.

If the power set point is greater than the idle power threshold, the controller 1316 determines whether a new fuel flow based on the power set point is less than a previous fuel flow based on the idle power threshold. If the previous fuel flow is greater than the new fuel flow, then the controller updates the idle power threshold to the power set point. The controller 1316 then outputs the globally optimum fuel consumption set point for the fuel cell module 14, corresponding to block 1206. If the previous fuel flow is less than the new fuel flow, then the controller 1316 performs an incremental adjustment of the power set point corresponding to an updated power set point. The closed loop controller 1316 then determines whether the updated power set point is less than the idle power threshold and the process continues until the idle power threshold is greater than the updated power set point.

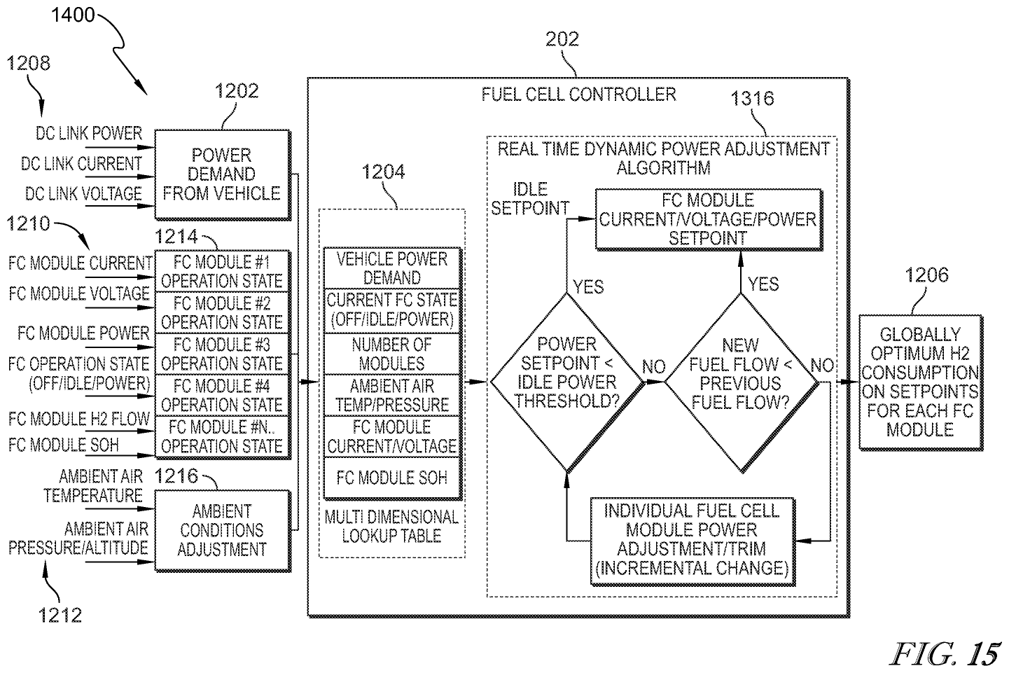

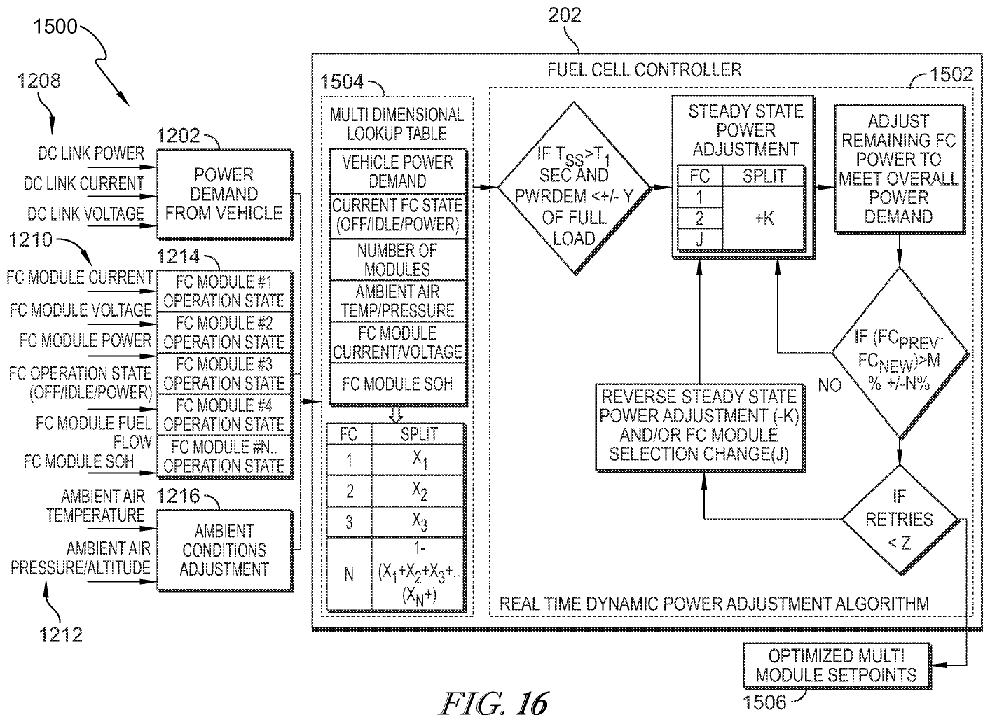

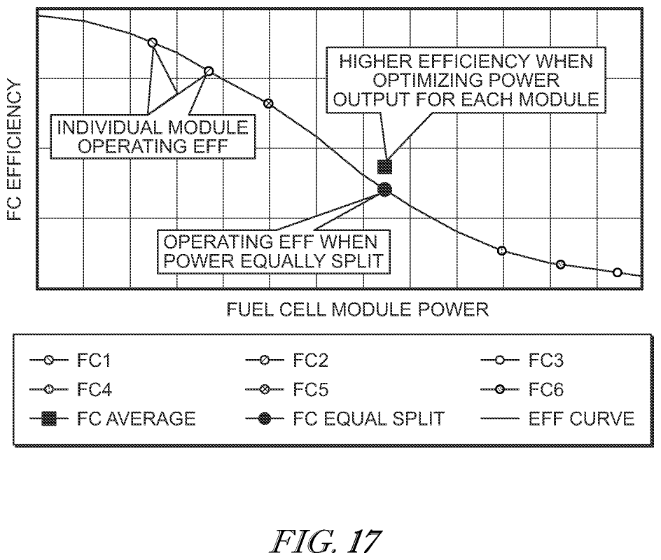

FIGS. 15 and 16 illustrate example hybrid control strategy systems 1400 and 1500, respectively, in accordance with the present disclosure. In applying the hybrid control strategy, the fuel cell controller 202 includes the closed loop controller 1316, as discussed in reference to FIG. 14, operating in conjunction with the open loop controller 1204, as discussed in reference to FIG. 13, to achieve an optimized operating mode. Thus, the fuel cell vehicle 100 including individual fuel cell modules 14 of either the same or different power ratings may achieve optimal operation (see, e.g., FIG. 17).

In one example, the open loop controller 1204 uses a static lookup of the power demand split between the fuel cell modules 14 based on the multi-dimensional table or relationship. Once static set points are made, the closed loop controller 1316 activates in response to the global power demand operating within a threshold of a steady state for a predefined time period. In this manner, the fuel cell controller 202 ensures further optimization of the fuel cell power set points at steady state. The fuel cell controller 202 is configured to make a predetermined power adjustment to a selected number of fuel cell modules 14 and check for improvement of overall fuel consumption numbers beyond a variation band. By performing this check, the fuel cell controller 202 ensures fuel consumption benefits can be detected and are not part of the ‘noise’. In response to detecting that the global fuel consumption improved, the fuel cell controller 202 is configured to continue refining the power set points until there is no more improvement to be made. In response to detecting that the fuel consumption did not improve, the fuel cell controller 202 is configured to reverse a last power adjustment and/or reverse power adjustment in the selected fuel cell modules 14. The fuel cell controller 202 may be configured to repeat for a predetermined number of computational cycles or period of time prior to finalizing a fixed set of power set points for the individual fuel cell modules 14.

In applying the hybrid control strategy of FIG. 16, the fuel cell controller 202 includes a closed loop controller 1502 operating in conjunction with an open loop controller 1504 to achieve an optimized operating mode. The open loop controller 1504 determines a power set point for each fuel cell module 14 based on the information from blocks 1202, 1214, and 1216. The closed loop controller 1502 then checks the power set point of each fuel cell module 14 to output an optimized multi-module set point in block 1506.

Hybrid control strategy 1500 allows idling between different fuel cell modules 14. Each fuel cell module 14 may provide a different amount of power to meet the power demand P of the vehicle 100. The strategy 1500 cycles between using different fuel cell modules 14 and/or adjusting the power from each fuel cell module 14 based on the SOH of each fuel cell module 14. The cycling minimizes the aging of one fuel cell module 14 over another fuel cell module 14.

If a time counter (T_{SS}) is greater than a calibratable time constant (T₁), and the power demand of the fuel cell module 14 based on the power set point from the open loop controller 1504 (PwrDem) is less than a power demand variation band (Y), then the power set point of the fuel cell module 14 will be adjusted. Based on the power demand P of the vehicle 100, and the adjusted power set point of the fuel cell module 14, the power set point of the remaining fuel cell modules 14 will then be adjusted to meet the overall power demand P of the vehicle 100.

T_{SS} is representative of a time counter for steady state power demand. T₁ is representative of a calibratable time constant. PwrDem is representative of an instantaneous power demand. Y is representative of a power demand variation band and may be implemented as an absolute value or relative percent. J is a selected fuel cell module 14 for steady state power adjustment. K is representative of a steady state power demand adjustment for each fuel cell module 14. FC_{PREV} and FC_{NEW} are representative of a previous and new fuel consumption values, respectively. Z is representative of a retry count and may be implemented as a time period, such as by providing a clock signal.

FIG. 17 is a graph illustrating a change in fuel efficiency of the plurality of fuel cell modules 14 with respect to a change in fuel cell module power. Higher efficiency is achieved when power output is optimized for each fuel cell module 14.

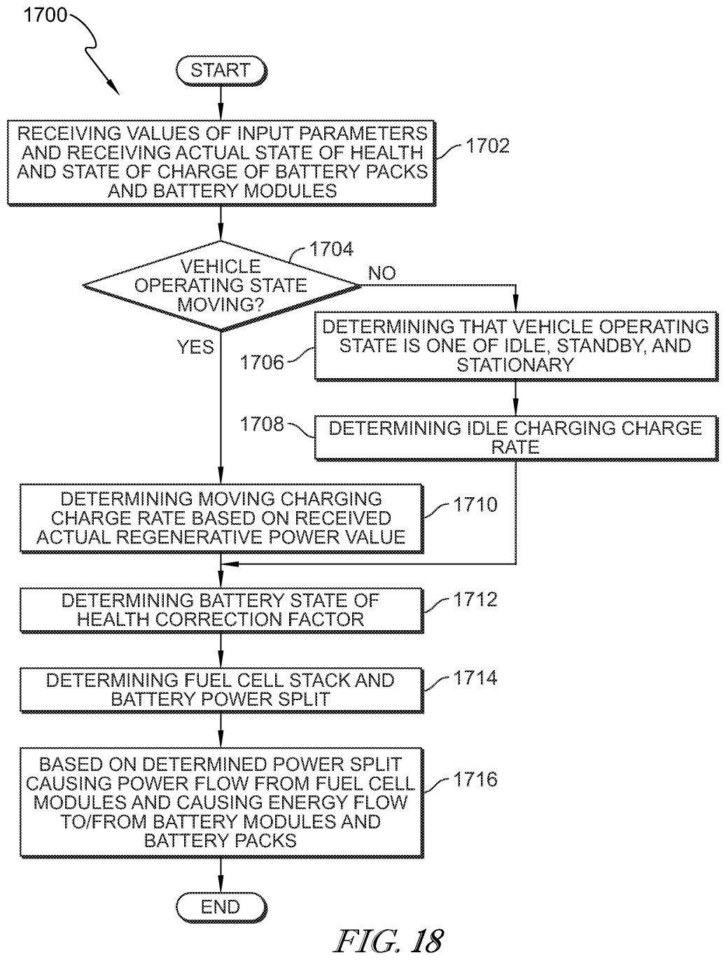

FIG. 18 illustrates an example process 1700 for controlling power flow from the plurality of fuel cell modules 14 and to and from the plurality of battery packs 158. One or more operations of the process 1700 may be executed by one of the fuel cell controllers 202. In other instances, one or more operations of the process 1700 may be executed by the fuel cell controller 202 and/or the battery controller 204 or by another one or more controller(s) of the fuel cell vehicle 100.

The process 1700 may begin at block 1702 where the fuel cell controller 202 receives values of one or more input parameters, such as, for example, actual battery SOC, target battery SOC, battery temperature, battery voltage, battery current, ambient temperature, and ambient pressure. In some instances, the fuel cell controller 202 is configured to receive actual SOH and SOC of the plurality of battery packs 158 and/or battery modules of the plurality of battery packs 158.

At block 1704 the fuel cell controller 202 determines whether the operating state of the fuel cell vehicle 100 is a moving state. In response to determining that the vehicle 100 is not moving, the fuel cell controller 202, at block 1706, determines that the operating state of the fuel cell vehicle 100 is one of an idle state, a standby state, and a stationary state. The fuel cell controller 202, at block 1708, determines an idle charging charge rate for the plurality of battery packs 158. In response to determining that the operating state of the vehicle 100 is a moving state, the fuel cell controller 202, at block 1710, determines a moving charging charge rate based on the received input parameter values and/or a received actual regenerative power value.

At block 1712, the fuel cell controller 202 determines a battery SOH correction factor. In one example, the fuel cell controller 202 may be configured to determine a battery SOH correction factor in accordance with one or more operations described in reference to FIGS. 13-16. At block 1714, the fuel cell controller 202 is configured to determine, based on the determined battery SOH correction factor, a power split between the plurality of fuel cell modules 14 and the plurality of battery packs 158.

At block 1716, the fuel cell controller 202 causes a flow of power and energy from the plurality of fuel cell modules 14 and to and from the plurality of battery packs 158 (including to and from individual modules of the plurality of battery packs 158) to meet power demand P of the vehicle 100 and/or to maintain the SOC of the plurality of battery packs 158. In one example, the fuel cell controller 202 causes a flow of power and energy based on and according to the determined power split. The process 1700 may then end. In some instances, the process 1700 may be repeated in response to receiving values of a plurality of input parameters and actual SOH and SOC of the plurality of battery packs 158 and/or battery modules or in response to another signal or command.

The system of the present disclosure is configured to apply a prioritization strategy to charge each of the plurality of battery packs 158 (or battery modules of each of the plurality of battery packs 158), where the SOH of at least one of the plurality of battery packs 158 (or battery modules of each of the plurality of battery packs 158) is different from the SOH of one or more other battery packs 158 of the plurality of battery packs 158 (or the SOH of at least one of a plurality of battery modules of at least one of the plurality of battery packs 158 is different from the SOH of one or more other battery modules of a same battery pack 158 or different battery packs 158). In one example, the system is configured to prioritize using battery packs 158 having a higher SOH, rather than battery packs 158 having a lower SOH to mitigate degradation of battery packs 158 that are farther along an aging continuum.

The system of the present disclose may be configured to determine a load/future load based on a specific duty cycle or lookahead data. The system may be configured to communicate that load to a corresponding controller, e.g., the battery controller 204, the fuel cell controller 202, and so on. The controller 202, 204 may be configured to rank each of the plurality of battery packs 158 with respect to one another based on SOH and/or SOC of that battery pack 158. In one example, the controller 202, 204 may be configured to prioritize meeting a present power load using energy of the plurality of battery packs 158 (and battery pack modules) having the highest SOH and having a SOC greater then a threshold over the plurality of battery packs 158 having a lower SOH.

To meet the demanded power load, the controller 202, 204 is configured to adjust the discharge rates from the plurality of battery packs 158 based on the SOH of those battery packs 158. In some instances, the controller 202, 204 may be configured to use one or more of the fuel cell modules 14 not being used to meet the demanded power load to charge the unused battery packs 158. The controller 202, 204 is configured to sequence and/or prioritize the charging of the unused battery packs 158 based on the SOH and SOC of that battery pack 158 (or one or more battery modules of that battery pack 158 or other battery packs 158 of the system) and/or based on vehicle lookahead data.

In this manner, the system is configured to use vehicle lookahead data and the battery packs 158 and battery modules having a different SOH to split the power to the battery packs 158 as a function of instantaneous load to achieve a predefined mission horizon. For example, in response to detecting that the vehicle 100 will operate in a regenerative mode, i.e., more throughput (based on mass and route), the system may be configured to prioritize using the battery packs 158 having a high SOH and using the battery packs 158 having a lower SOH during other operating modes. The controller 202, 204 is configured to adjust operating conditions to affect aging of the battery packs 158 to align with a common service/rebuild interval or one that is preferred by the end user. The battery management system is configured to modify power capability of each subsystem by, for example, modifying charging rates of battery packs 158 having a lower SOH, to meet the power demand P of the vehicle 100 using a different/modified power split under different operating conditions.

The controller 202, 204 may be configured to rank each of the plurality of fuel cell modules 14 based on a value of the SOH of each of the plurality of fuel cell modules 14, e.g., with the fuel cell module 14 having a largest value of SOH or having a SOH greater than a first predefined threshold being ranked first, another fuel cell module 14 having a second largest value of SOH or having a SOH greater than a second predefined threshold and less than the first predefined threshold being ranked below the first rank, and so on. In response to detecting that the power demand P of the vehicle 100 may be met by a subset of (e.g., fewer than all and including one) the fuel cell modules 14, the controller 202, 204 may be configured to cause the power demand P of the vehicle 100 to be met using the fuel cell module 14 (or one or more fuel cell stacks 12 of the same or different fuel cell modules 14) having a greater SOH, e.g., the greatest value of SOH or ranked first, the second greatest value of SOH or ranked second or below the first, based on the rank by SOH, as described above.

In another example, in response to detecting that the power demand P of the vehicle 100 may be met by a subset of (i.e., fewer than all and including one) the fuel cell modules 14, the controller 202, 204 may be configured to prioritize power demand P of the vehicle 100 to be met (i.e., power provided) by the fuel cell modules 14 having a higher SOH ranking. In response to the SOC of the plurality of battery packs 158 being less than a predefined threshold, the controller 202, 204 may be configured to cause one or more of the plurality of fuel cell modules 14 having a SOH less than a predefined threshold (including, for example, the fuel cell modules 14 having a lowest SOH) and currently not providing power to the vehicle 100 to charge the battery packs 158. Using a subset of the plurality of fuel cell modules 14 having a SOH rank less than a threshold rank, the controller 202, 204 may be configured to charge the battery packs 158 at a constant rate to improve the life of the fuel cell modules 14. The controller 202, 204 may prioritize charging of these battery packs 158 based on a SOH of the fuel cell modules 14 and/or the SOC and SOH of the plurality of battery packs 158. For example, the controller 202, 204 is configured to use one or more of the plurality of fuel cell modules 14 that are not supplying power (e.g., are idle) to the vehicle 100 to charge one or more of the plurality of battery packs 158 having the lowest SOC.

Benefits of the system of the present disclosure include ensuring a target SOC of the battery pack 158 is maintained so that sufficient energy and power from the battery pack 158 can be provided during sustained power demand situations. The system provides optimizing fuel cell 20 and battery 158 component sizing leading to a significant reduction on cost of the system. The system provides significant reduction in operational costs to a vehicle operator by optimizing fuel consumption from the fuel cell modules 14 by ensuring an optimal battery SOC. The disclosed system may be used in conjunction with the fuel cell-battery power split controller 202, 204 to further optimize fuel consumption and reduce operating costs. The system improves component life of the fuel cell modules 14 by reducing transient power demand on the fuel cell modules 14 and improving component life of the battery packs 158 by compensating based on a SOH of one or more components of the battery packs 158.

The following described aspects of the present invention are contemplated and non-limiting:

A first aspect of the present invention relates to a system for a fuel cell vehicle. The system comprises a plurality of fuel cell modules, a plurality of battery packs, and a controller. At least one of the plurality of fuel cell modules has a state of health (SOH) different from a corresponding SOH of another fuel cell module in the plurality of fuel cell modules. Each battery pack includes a plurality of battery cells. At least one of the plurality of battery packs has a SOH different from a corresponding SOH of another battery pack in the plurality of battery packs. The controller is communicatively coupled to the plurality of fuel cell modules and the plurality of battery packs. The controller is configured to monitor and control operation of the plurality of fuel cell modules or the plurality of battery packs. The controller is configured to receive a power demand of the vehicle. The controller is configured to determine a power split between the plurality of fuel cell modules and the plurality of battery packs based on an operating phase of the vehicle. The controller is configured to cause a flow of power based on a determined power split from the plurality of fuel cell modules and from the plurality of battery packs to meet the power demand.

A second aspect of the present invention relates to a method for a fuel cell vehicle. The method comprises receiving a plurality of input parameters, an actual state of health (SOH) of a battery, and a state of charge (SOC) of the battery, determining an operating state of the vehicle, determining a battery SOH correction factor, determining a power split between a plurality of fuel cell modules and the battery, and causing a flow of power from the plurality of fuel cell modules and to and from the battery based on the determined power split.

According to a third aspect, described herein, a system for a fuel cell vehicle comprises a plurality of fuel cell modules, a plurality of battery packs, and a controller. Each fuel cell module of the plurality of fuel cell modules includes a plurality of fuel cell stacks. Each battery pack of the plurality of battery packs includes a plurality of battery modules. At least one of the plurality of battery modules has a state of health (SOH) different from a corresponding SOH of another battery module in the plurality of battery modules. The controller is communicatively coupled to monitor and control operation of the plurality of fuel cell modules and the plurality of battery packs. The controller is configured to receive a power demand. The controller is configured to determine a power set point for each of the plurality of fuel cell stacks of each of the plurality of fuel cell modules. The controller is configured to cause a flow of power from each of the plurality of fuel cell stacks of each of the plurality of fuel cell modules based on the determined power set point of each of the plurality of fuel cell stacks.

In the first aspect of the present invention, the controller may be configured to determine the power split based on at least one of the SOH of the plurality of battery packs, the SOH of the plurality of fuel cell modules, and a state of charge (SOC) of the plurality of battery packs. In the first aspect of the present invention, the plurality of battery cells may be combined to provide a plurality of battery modules, and wherein a SOH of at least one of the plurality of battery modules may be different from a SOH of at least one other of the plurality of battery modules.

In the first aspect of the present invention, the controller may be configured to, in response to the power demand being greater than a threshold, determine an even power split between the plurality of fuel cell modules and the plurality of battery packs and cause the flow of power from the plurality of fuel cells modules and the plurality of battery packs to power a traction motor to propel the vehicle. In the first aspect of the present invention, the controller may be configured to, in response to input parameters, determine a vehicle operational state, determine a battery power rate based on a relational or lookup model, and cause at least one of the events of powering a traction motor to propel the vehicle, powering vehicle accessory systems, or causing the plurality of fuel cell modules to charge the plurality of battery packs.

In the first aspect of the present invention, the controller may be configured to cause the plurality of fuel cell modules to charge the plurality of battery packs further in response to detecting a truck bed of the vehicle is active. In the first aspect of the present invention, the controller may be configured to determine a battery SOH correction factor to be used in determining the power split between the plurality of fuel cell modules and the plurality of battery packs.

In the second aspect of the present invention, the method may further comprise, in response to determining that the operating state of the vehicle is one of an idle state, a standby state, or a stationary state, determining a battery charge rate for charging the battery while the vehicle is in the idle state, the standby state, or the stationary state. In the second aspect of the present invention, the method may further comprise in response to determining that the operating state of the vehicle is a moving state, determining a battery charge rate for charging the battery while the vehicle is moving.

In the second aspect of the present invention, the plurality of input parameters may include one of an actual battery SOC, a target battery SOC, a battery temperature, a battery voltage, a battery current, an ambient temperature, and an ambient pressure. In the second aspect of the present invention, the power split may be determined based on a predictive fuel cell power demand estimation. In the second aspect of the present invention, the predictive fuel cell power demand estimation may be provided by a cloud-based analytical system. In the second aspect of the present invention, the cloud-based analytical system may determine the predictive fuel cell power demand estimation based on values of one of a speed of the vehicle, a weight of the vehicle, a wheel power, a configuration of the vehicle, an ambient temperature, an upcoming route target speed, an upcoming route target grade, or an accessory power.

In the third aspect of the present invention, to determine the corresponding power set point may include to determine whether the determined power set point is less than an idle power threshold, and wherein the controller may be configured to, in response to the determined power set point being less than the idle power threshold, update a value of the idle power threshold to correspond to a value of the determined power set point. In the third aspect of the present invention, the controller may be configured to, in response to the determined power set point being greater than the idle power threshold, determine whether a new fuel flow based on the determined power set point is less than a previous fuel flow based on the idle power threshold.

In the third aspect of the present invention, the controller may be configured to, in response to the new fuel flow based on the determined power set point being less than the previous fuel flow based on the idle power threshold, update the value of the idle power threshold to correspond to the value of the determined power set point. In the third aspect of the present invention, the controller may be configured to, in response to the new fuel flow based on the determined power set point being greater than the previous fuel flow based on the idle power threshold, incrementally adjust the determined power set point to correspond to an updated determined power set point.

The features illustrated or described in connection with one exemplary embodiment may be combined with any other feature or element of any other embodiment described herein. Such modifications and variations are intended to be included within the scope of the present disclosure. Further, a person skilled in the art will recognize that terms commonly known to those skilled in the art may be used interchangeably herein.

The above embodiments are described in sufficient detail to enable those skilled in the art to practice what is claimed and it is to be understood that logical, mechanical, and electrical changes may be made without departing from the spirit and scope of the claims. The detailed description is, therefore, not to be taken in a limiting sense.

As used herein, an element or step recited in the singular and proceeded with the word “a” or “an” should be understood as not excluding plural of said elements or steps, unless such exclusion is explicitly stated. Furthermore, references to “one embodiment” of the presently described subject matter are not intended to be interpreted as excluding the existence of additional embodiments that also incorporate the recited features. Specified numerical ranges of units, measurements, and/or values comprise, consist essentially or, or consist of all the numerical values, units, measurements, and/or ranges including or within those ranges and/or endpoints, whether those numerical values, units, measurements, and/or ranges are explicitly specified in the present disclosure or not.

Unless defined otherwise, technical and scientific terms used herein have the same meaning as is commonly understood by one of ordinary skill in the art to which this disclosure belongs. The terms “first,” “second,” “third” and the like, as used herein do not denote any order or importance, but rather are used to distinguish one element from another. The term “or” is meant to be inclusive and mean either or all of the listed items. In addition, the terms “connected” and “coupled” are not restricted to physical or mechanical connections or couplings, and can include electrical connections or couplings, whether direct or indirect.

Moreover, unless explicitly stated to the contrary, embodiments “comprising,” “including,” or “having” an element or a plurality of elements having a particular property may include additional such elements not having that property. The term “comprising” or “comprises” refers to a composition, compound, formulation, or method that is inclusive and does not exclude additional elements, components, and/or method steps. The term “comprising” also refers to a composition, compound, formulation, or method embodiment of the present disclosure that is inclusive and does not exclude additional elements, components, or method steps.

The phrase “consisting of” or “consists of” refers to a compound, composition, formulation, or method that excludes the presence of any additional elements, components, or method steps. The term “consisting of” also refers to a compound, composition, formulation, or method of the present disclosure that excludes the presence of any additional elements, components, or method steps.

The phrase “consisting essentially of” or “consists essentially of” refers to a composition, compound, formulation, or method that is inclusive of additional elements, components, or method steps that do not materially affect the characteristic(s) of the composition, compound, formulation, or method. The phrase “consisting essentially of” also refers to a composition, compound, formulation, or method of the present disclosure that is inclusive of additional elements, components, or method steps that do not materially affect the characteristic(s) of the composition, compound, formulation, or method steps.

Approximating language, as used herein throughout the specification and claims, may be applied to modify any quantitative representation that could permissibly vary without resulting in a change in the basic function to which it is related. Accordingly, a value modified by a term or terms, such as “about,” and “substantially” is not to be limited to the precise value specified. In some instances, the approximating language may correspond to the precision of an instrument for measuring the value. Here and throughout the specification and claims, range limitations may be combined and/or interchanged. Such ranges are identified and include all the sub-ranges contained therein unless context or language indicates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances, the modified term may sometimes not be appropriate, capable, or suitable.

It is to be understood that the above description is intended to be illustrative, and not restrictive. For example, the above-described embodiments (and/or aspects thereof) may be used individually, together, or in combination with each other. In addition, many modifications may be made to adapt a particular situation or material to the teachings of the subject matter set forth herein without departing from its scope. While the dimensions and types of materials described herein are intended to define the parameters of the disclosed subject matter, they are by no means limiting and are exemplary embodiments. Many other embodiments will be apparent to those of skill in the art upon reviewing the above description. The scope of the subject matter described herein should, therefore, be determined with reference to the appended claims, along with the full scope of equivalents to which such claims are entitled.

This written description uses examples to disclose several embodiments of the subject matter set forth herein, including the best mode, and also to enable a person of ordinary skill in the art to practice the embodiments of disclosed subject matter, including making and using the devices or systems and performing the methods. The patentable scope of the subject matter described herein is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A system for a fuel cell vehicle, the system comprising:
a plurality of fuel cell modules, at least one of the plurality of fuel cell modules having a state of health (SOH) different from a corresponding SOH of another fuel cell module in the plurality of fuel cell modules;
a plurality of battery packs, each battery pack including a plurality of battery cells, at least one of the plurality of battery packs having a SOH different from a corresponding SOH of another battery pack in the plurality of battery packs; and
a controller communicatively coupled to the plurality of fuel cell modules and the plurality of battery packs, the controller being configured to:
monitor and control operation of the plurality of fuel cell modules or the plurality of battery packs,
receive a power demand of the vehicle,
determine a power split between the plurality of fuel cell modules and the plurality of battery packs based on an operating phase of the vehicle, and
cause a flow of power based on a determined power split from the plurality of fuel cell modules and from the plurality of battery packs to meet the power demand.

2. The system of claim 1, wherein the controller is configured to determine the power split based on at least one of the SOH of the plurality of battery packs, the SOH of the plurality of fuel cell modules, and a state of charge (SOC) of the plurality of battery packs.

3. The system of claim 1, wherein the plurality of battery cells are combined to provide a plurality of battery modules, and wherein a SOH of at least one of the plurality of battery modules is different from a SOH of at least one other of the plurality of battery modules.

4. The system of claim 1, wherein the controller is configured to, in response to the power demand being greater than a threshold, determine an even power split between the plurality of fuel cell modules and the plurality of battery packs and cause the flow of power from the plurality of fuel cell modules and the plurality of battery packs to power a traction motor to propel the vehicle.

5. The system of claim 4, wherein the even power split is determined in further response to detecting that the vehicle is moving up an incline.

6. The system of claim 1, wherein the controller is configured to, in response to input parameters, determine a vehicle operational state, determine a battery power rate based on a relational or lookup model, and cause at least one of the events of powering a traction motor to propel the vehicle, powering vehicle accessory systems, or causing the plurality of fuel cell modules to charge the plurality of battery packs.

7. The system of claim 6, wherein the controller is configured to cause the plurality of fuel cell modules to charge the plurality of battery packs further in response to detecting a truck bed of the vehicle is active.

8. The system of claim 1, wherein the controller is configured to determine a battery SOH correction factor to be used in determining the power split between the plurality of fuel cell modules and the plurality of battery packs.

9. A method for a fuel cell vehicle, the method comprising:
receiving a plurality of input parameters, an actual state of health (SOH) of a battery, and a state of charge (SOC) of the battery;
determining an operating state of the vehicle;
determining a battery SOH correction factor;
determining a power split between a plurality of fuel cell modules and the battery; and
causing a flow of power from the plurality of fuel cell modules and to and from the battery based on the determined power split.

10. The method of claim 9 further comprising, in response to determining that the operating state of the vehicle is one of an idle state, a standby state, or a stationary state, determining a battery charge rate for charging the battery while the vehicle is in the idle state, the standby state, or the stationary state.

11. The method of claim 9 further comprising, in response to determining that the operating state of the vehicle is a moving state, determining a battery charge rate for charging the battery while the vehicle is moving.

12. The method of claim 9, wherein the plurality of input parameters include one of an actual battery SOC, a target battery SOC, a battery temperature, a battery voltage, a battery current, an ambient temperature, and an ambient pressure.

13. The method of claim 9, wherein the power split is determined based on a predictive fuel cell power demand estimation.

14. The method of claim 13, wherein the predictive fuel cell power demand estimation is provided by a cloud-based analytical system.

15. The method of claim 14, wherein the cloud-based analytical system determines the predictive fuel cell power demand estimation based on values of one of a speed of the vehicle, a weight of the vehicle, a wheel power, a configuration of the vehicle, an ambient temperature, an upcoming route target speed, an upcoming route target grade, or an accessory power.

16. A system for a fuel cell vehicle, the system comprising:
a plurality of fuel cell modules, each fuel cell module of the plurality of fuel cell modules including a plurality of fuel cell stacks;
a plurality of battery packs, each battery pack of the plurality of battery packs including a plurality of battery modules, at least one of the plurality of battery modules having a state of health (SOH) different from a corresponding SOH of another battery module in the plurality of battery modules; and
a controller communicatively coupled to monitor and control operation of the plurality of fuel cell modules and the plurality of battery packs, the controller being configured to:
receive a power demand,
determine a power set point for each of the plurality of fuel cell stacks of each of the plurality of fuel cell modules, and
cause a flow of power from each of the plurality of fuel cell stacks of each of the plurality of fuel cell modules based on the determined power set point of each of the plurality of fuel cell stacks.

17. The system of claim 16, wherein to determine the power set point includes to determine whether the determined power set point is less than an idle power threshold, and wherein the controller is configured to, in response to the determined power set point being less than the idle power threshold, update a value of the idle power threshold to correspond to a value of the determined power set point.

18. The system of claim 17, wherein the controller is configured to, in response to the determined power set point being greater than the idle power threshold, determine whether a new fuel flow based on the determined power set point is less than a previous fuel flow based on the idle power threshold.

19. The system of claim 18, wherein the controller is configured to, in response to the new fuel flow based on the determined power set point being less than the previous fuel flow based on the idle power threshold, update the value of the idle power threshold to correspond to the value of the determined power set point.

20. The system of claim 19, wherein the controller is configured to, in response to the new fuel flow based on the determined power set point being greater than the previous fuel flow based on the idle power threshold, incrementally adjust the determined power set point to correspond to an updated determined power set point.
